(19) United States
(12) Patent Application Publication
(10) Pub. No.: US 2026/0304745 A1
(43) Pub. Date: Oct. 1, 2026

(54) SEMICONDUCTOR DEVICE

(71) Applicant: Samsung Electronics Co., Ltd., Suwon-si (KR)

(72) Inventor: Taemin Cha, Suwon-si (KR)

(73) Assignee: Samsung Electronics Co., Ltd., Suwon-si (KR)

(21) Appl. No.: 19/405,169

(22) Filed: Dec. 1, 2025

(30) Foreign Application Priority Data
Mar. 26, 2025 (KR) 10-2025-0038816

(51) Int. Cl. H10B 12/00

(52) U.S. Cl. CPC H10B 12/315; H10B 12/05; H10B 12/50

(57) ABSTRACT

The present disclosure relates to a semiconductor device, and a semiconductor device according to embodiments includes a substrate, a bit line positioned on the substrate and extending in a first direction, a word line positioned on the bit line and extending in a second direction intersecting the first direction, an active pattern extending in a third direction substantially perpendicular to the first direction and the second direction, and a cell capacitor positioned on the active pattern, the active pattern includes a first portion extending in the second direction, and a plurality of second portions protruding from the first portion in a first direction and positioned between the first portion and the word line.

### CROSS-REFERENCE TO RELATED APPLICATIONS

This application claims priority to and the benefit of Korean Patent Application No. 10-2025-0038816 filed with the Korean Intellectual Property Office on Mar. 26, 2025, the entire contents of which are incorporated herein by reference.

### BACKGROUND

The present disclosure relates to a semiconductor device.

There is a need for technologies to increase the degrees of integration of semiconductor devices. In the case of two-dimensional semiconductor devices, the degrees of integration are mainly determined by the areas occupied by unit memory cells, and the degrees of integration in this aspect may depend on the levels of micropatterning techniques.

By the way, the micropatterning techniques require expensive equipment. Therefore, although the degrees of integration of two-dimensional semiconductor devices are increasing, it is still limited. Accordingly, three-dimensional memory devices having memory cells arranged in three dimensions are being proposed.

As components which are included in semiconductor memory devices become more integrated and miniaturized, it is important to minimize the influence between components included in semiconductor devices to improve the operating performance of the semiconductor devices.

### SUMMARY

The present disclosure attempts to provide a semiconductor device with improved reliability and productivity.

A semiconductor device according to embodiments includes a substrate, a bit line positioned on the substrate and extending in a first direction, a word line positioned on the bit line and extending in a second direction intersecting the first direction, an active pattern extending in a third direction substantially perpendicular to the first direction and the second direction, and a cell capacitor positioned on the active pattern, the active pattern includes a first portion extending in the second direction, and a plurality of second portions protruding from the first portion in a first direction and positioned between the first portion and the word line.

A semiconductor device according to embodiments includes a substrate, a bit line positioned on the substrate and extending in a first direction, a word line positioned on the bit line and extending in a second direction intersecting the first direction, an active pattern extending in a third direction substantially perpendicular to the first direction and the second direction, a cell capacitor positioned on the active pattern, and a storage contact positioned between the active pattern and the cell capacitor, the active pattern includes a first portion extending in the second direction, and a plurality of second portions protruding from the first portion in a first direction and positioned between the first portion and the word line, each of the plurality of second portions includes a first dopant region connected to the bit line, a second dopant region connected to the storage contact, and a channel region positioned between the first dopant region and the second dopant region.

A semiconductor device according to embodiments includes a substrate including a cell array region and a peripheral circuit region adjacent to the cell array region, a bit line positioned on the substrate and extending in a first direction, a first word line and a second word line positioned on the bit line and extending in a second direction intersecting the first direction, a plurality of active patterns positioned between the first word line and the second word line and extending in a third direction substantially perpendicular to the first direction and the second direction, a plurality of cell capacitors positioned on the plurality of active patterns, and a plurality of storage contacts respectively positioned between the plurality of active patterns and the plurality of cell capacitors, each of the plurality of active patterns includes a first portion extending in the second direction from the cell array region to the peripheral circuit region, and a plurality of second portions protruding from the first portion toward one side or the other side in the first direction, and positioned between the first portion and either the first word line or the second word line, each of the plurality of second portions includes a first dopant region connected to the bit line, a second dopant region connected to each of the storage contacts, and a channel region positioned between the first dopant region and the second dopant region.

A manufacturing method of manufacturing a semiconductor device according to embodiments includes the steps of preparing a sub-substrate and an active layer positioned on the sub-substrate, patterning the active layer to form a plurality of active patterns including a first portion extending in a first direction and a plurality of second portions protruding from the first portion toward to one side or the other side in a second direction intersecting the first direction, forming a preliminary word line between the plurality of active patterns, forming a plurality of storage contacts on the plurality of active patterns, forming a plurality of cell capacitors on the plurality of storage contacts, removing the sub-substrate and then patterning the preliminary word lines to form a word line extending in the first direction, and forming a bit line extending in the second direction on the plurality of active patterns.

The method of manufacturing a semiconductor device according to embodiments may further include, before forming the plurality of active patterns, patterning the active layer to form a separation insulating pattern extending in the first direction, the separation insulating pattern may be positioned between the plurality of active patterns.

The method of manufacturing a semiconductor device according to embodiments may further include forming a first active capping pattern between the first portion and the bit line.

The method of manufacturing a semiconductor device according to embodiments may further include forming a second active capping pattern between the first portion and the storage contact.

The method of manufacturing a semiconductor device according to embodiments may further include forming a mask pattern that covers the first portion and exposes the second portion, and forming, in the second portion exposed by the mask pattern, a first dopant region connected to the bit line, a second dopant region connected to the storage contact, and a channel region positioned between the first dopant region and the second dopant region.

The method of manufacturing a semiconductor device according to embodiments may further include doping a dopant into the first portion.

A width of the first portion in the second direction and a width of the second portion in the second direction may be different.

Each of the first portion and the second portion extends in a third direction perpendicular to the first direction and the second direction, and a length of the first portion in the third direction may be different from a length of the second portion in the third direction.

According to embodiments, the plurality of active patterns may include a portion serving as a channel region of a memory transistor and a portion for removing excess holes that are generated and accumulated during the operation of the memory transistor, thereby preventing or suppressing a floating body effect (FBE).

Accordingly, the leakage current of the memory transistor may be reduced, thereby improving the reliability and productivity of the semiconductor device.

### BRIEF DESCRIPTION OF THE DRAWINGS

FIG. 1 is a plan view of a semiconductor device according to embodiments.

FIG. 2 is a plan view illustrating a part of a semiconductor device according to embodiments.

FIG. 3 is a cross-sectional view illustrating a cross-section taken along lines A-A′ and B-B′ of FIG. 1.

FIG. 4 is a cross-sectional view illustrating a cross-section taken along lines C-C′ of FIG. 1.

FIG. 5 is a partial enlarged view of region P1 of FIG. 4.

FIGS. 6 to 10 and 12 are cross-sectional views of a semiconductor device according to some embodiments.

FIG. 11 is a plan view illustrating a part of a semiconductor device according to some embodiments.

FIG. 13 to FIG. 22 are cross-sectional views illustrating a manufacturing method of the semiconductor device according to embodiments.

### DETAILED DESCRIPTION

In the following detailed description, only certain embodiments have been shown and described, simply by way of illustration. The present invention may be variously implemented and is not limited to the following embodiments.

The drawings and description are to be regarded as illustrative in nature and not restrictive. Like reference numerals designate like elements throughout the specification.

In addition, the size and thickness of each configuration shown in the drawings are arbitrarily shown for understanding and ease of description, but the present invention is not limited thereto. In the drawings, the thickness of layers, films, panels, regions, etc., are exaggerated for clarity. Further, in the drawings, for understanding and ease of description, the thickness of some layers and areas is exaggerated.

Further, it will be understood that when an element such as a layer, film, region, or substrate is referred to as being “on” another element, it may be directly on the other element or intervening elements may also be present. In contrast, when an element is referred to as being “directly on” another element, there are no intervening elements present. Further, when an element is “on” a reference portion, the element is located above or below the reference portion, and it does not necessarily mean that the element is located “above” or “on” in a direction opposite to gravity.

In addition, in the entire specification, unless explicitly described to the contrary, the word “comprise”, and variations such as “comprises” or “comprising”, will be understood to imply the inclusion of stated elements but not the exclusion of any other elements.

Further, in the entire specification, when it is referred to as “on a plane”, it means when a target part is viewed from above, and when it is referred to as “on a cross-section”, it means when the cross-section obtained by cutting a target part vertically is viewed from the side.

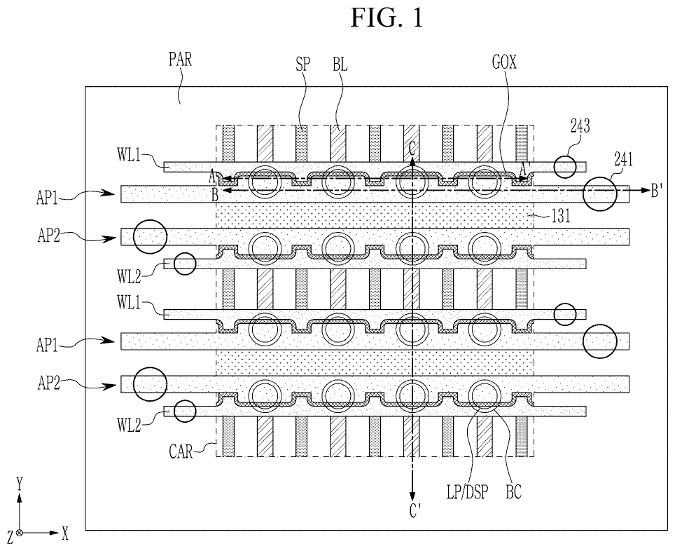

Hereinafter, a semiconductor device according to embodiments will be described below with reference to FIGS. 1 to 5.

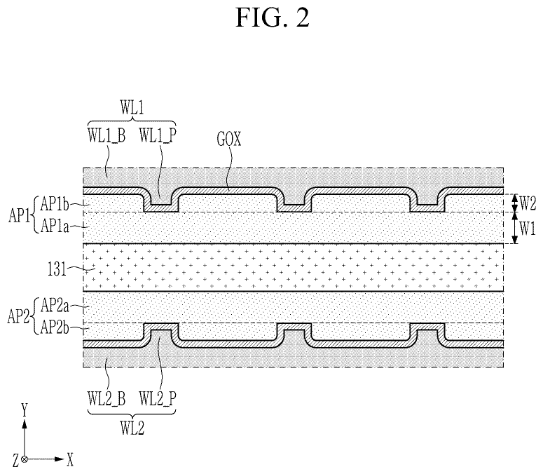

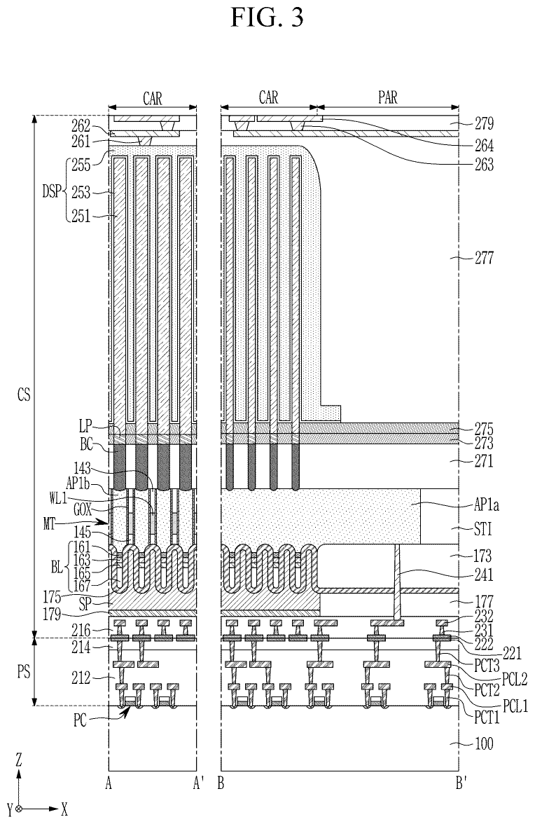

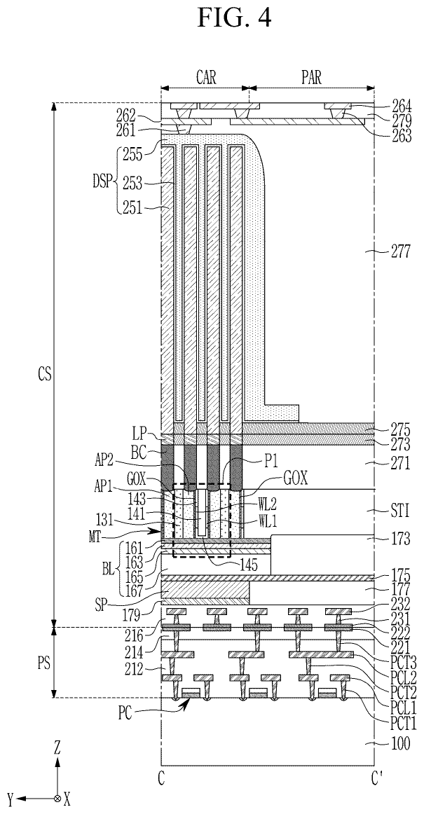

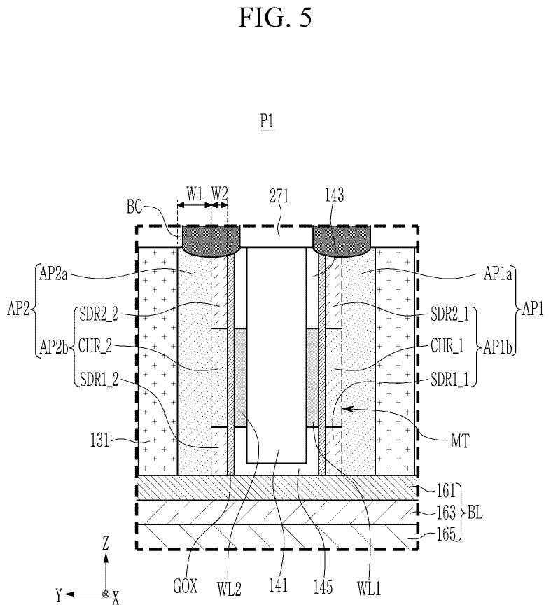

FIG. 1 is a plan view of a semiconductor device according to embodiments. FIG. 2 is a plan view illustrating a part of a semiconductor device according to embodiments. FIG. 3 is a cross-sectional view illustrating a cross-section taken along lines A-A′ and B-B′ of FIG. 1. FIG. 4 is a cross-sectional view illustrating a cross-section taken along lines C-C′ of FIG. 1. FIG. 5 is a partial enlarged view of region P1 of FIG. 4.

In FIG. 2, the illustration of the remaining components is omitted in order to describe the arrangement of some of the components included in the semiconductor device.

Referring to FIGS. 1 to 5, the semiconductor device according to the embodiments may include a substrate 100, and a peripheral circuit structure PS and a cell structure CS which are positioned on the substrate 100.

The substrate 100 may include a cell array region CAR, and a peripheral circuit region PAR defined around the cell array region CAR. For example, the peripheral circuit region PAR may be positioned adjacent to the cell array region CAR, and surround the cell array region CAR. However, the arrangement of the cell array region CAR and the peripheral circuit region PAR is not limited thereto, and may be variously changed.

In the cell array region CAR, a plurality of memory cells which includes memory transistors MT and cell capacitors DSP, word lines WL1 and WL2 and bit line BL which are connected to them, and so on may be positioned, and in the peripheral circuit region PAR, a plurality of contacts 241 and 243 connected to the components positioned in the cell array region CAR may be positioned. This will be described in more detail below.

A memory cell may include one memory transistor MT and one cell capacitor DSP. Depending on whether there is any charge stored in the cell capacitor DSP, two states distinguishable from each other may be determined, and the cell capacitor DSP may act as a memory element.

A gate electrode of the memory transistor MT may be connected to a word line WL, and a first source/drain electrode of the memory transistor MT may be connected to one terminal of the cell capacitor DSP, and a second source/drain electrode of the memory transistor MT may be connected to a bit line BL. This will be described in more detail below.

A semiconductor device according to embodiments may include a plurality of memory cells including vertical channel transistor (VCT). However, the type of the semiconductor device is not limited thereto and may be variously changed.

In some embodiments, the cell structure CS may include at least one of various types of semiconductors. For example, the cell structure CS may include a two-dimensional (2D) memory such as a DRAM having a Buried Channel Array Transistor (BCAT) structure. As another example, the cell structure CS may include a three-dimensional (3D) memory such as a Vertically Stacked (VS) DRAM, a 3D ferroelectric field-effect transistor (FeFET), or a 3D monolithic memory.

As another example, the cell structure CS may be a non-volatile memory device, and more specifically, may be a NAND flash memory device.

As another example, the cell structure CS may include various types of devices such as a Fin field-effect transistor (Fin FET), a gate-all-around field-effect transistor (GAA-FET) (e.g., a multi-bridge channel field-effect transistor (MBCFETTM)), a three-dimensional stacked field-effect transistor (3DS-FET), and a complementary field-effect transistor (CFET).

Hereinafter, a description will be provided on the assumption that the cell structure CS of the semiconductor device according to embodiments is a DRAM having a vertical channel transistor (VCT) structure.

The substrate 100 may be a silicon substrate, or may contain silicon germanium, indium antimonide, a lead tellurium compound, indium arsenide, indium phosphide, gallium arsenide, or gallium antimonide, but is not limited thereto, and the material which is contained in the substrate 100 may be variously changed.

In embodiments, the peripheral circuit structure PS and the cell structure CS which are positioned on the substrate 100 may be positioned so as to overlap in a vertical direction. For example, the peripheral circuit structure PS and the cell structure CS may be sequentially stacked on the substrate 100. In other words, the cell structure CS may be positioned on the peripheral circuit structure PS. However, the present disclosure is not limited thereto, and the stacking relationship of the cell structure CS and the peripheral circuit structure PS may be variously changed. For example, the cell structure CS may be positioned adjacent to and side by side with the peripheral circuit structure PS in a horizontal direction. As another example, the cell structure CS may be positioned below the peripheral circuit structure PS so as to overlap the peripheral circuit structure in the vertical direction.

Hereinafter, the configuration and structure of the semiconductor device according to embodiments will be described in detail.

Embodiments will be described on the assumption of the structure in which the cell structure CS is positioned on the peripheral circuit structure PS.

The peripheral circuit structure PS may be positioned on the substrate 100. The peripheral circuit structure PS may be positioned between the substrate 100 and the cell structure CS.

The peripheral circuit structure PS may be positioned throughout the cell array region CAR and peripheral circuit region PAR of the substrate 100. In other words, a portion of the peripheral circuit structure PS may be positioned on the cell array region CAR of the substrate 100, and the other portion may be positioned on the peripheral circuit region PAR.

Although not shown in the drawings, the peripheral circuit structure PS may include a core region and a peripheral region. The core region and the peripheral region may be collectively referred to as the logic region or the peripheral circuit region.

The core region may include a core bank, and the core bank may include core circuits such as a word line driver, a sense amplifier, a row decoder, a column decoder, and a read/write circuit (R/W circuit).

The peripheral region may include peripheral circuits such as a timing register, an address register, a data input register, a data output register, and a data input/output terminal.

The peripheral circuit structure PS may include a peripheral circuit PC for driving the components positioned in the cell structure CS. For example, the peripheral circuit PC may include the core circuits and/or the peripheral circuits mentioned above.

The peripheral circuit structure PS may include the peripheral circuit PC, peripheral circuit contacts PCT1, PCT2, and PCT3, peripheral circuit wiring lines PCL1 and PCL2, a peripheral circuit insulating layer 212, a first bonding insulating layer 214, and a plurality of first bonding pads 221.

The peripheral circuit PC may be positioned on the substrate 100. The peripheral circuit PC may be, for example, a sensing transistor, a transfer transistor, a driving transistor, etc. However, the type of the transistor of the peripheral circuit PC may be variously changed depending on the design of the semiconductor device.

The peripheral circuit insulating layer 212 may cover the peripheral circuit PC. In other words, the peripheral circuit insulating layer 212 may cover the side surfaces and upper surface of the peripheral circuit PC. The peripheral circuit insulating layer 212 may contain an insulating material. For example, the peripheral circuit insulating layer 212 may contain silicon oxide, silicon nitride, silicon oxynitride, and/or a low-dielectric constant material. However, the present disclosure is not limited thereto.

The peripheral circuit contacts PCT1, PCT2, and PCT3 and the peripheral circuit wiring lines PCL1 and PCL2 may be positioned in the peripheral circuit insulating layer 212.

The first peripheral circuit wiring line PCL1 may be connected to the peripheral circuit PC through the first peripheral circuit contact PCT1. The first peripheral circuit wiring line PCL1 may be connected to at least a source/drain region of the peripheral circuit PC positioned on one side, through the first peripheral circuit contact PCT1. The first peripheral circuit wiring line PCL1 and the second peripheral circuit wiring line PCL2 may be connected by the second peripheral circuit contact PCT2.

Although it is shown in the drawings that, in embodiments, the peripheral circuit insulating layer 212 consists of a single layer, the present disclosure is not limited thereto, and the peripheral circuit insulating layer 212 may consist of multiple layers containing the same material and/or different materials.

When the peripheral circuit insulating layer 212 consists of multiple layers, at least some of the first peripheral circuit contact PCT1, the second peripheral circuit contact PCT2, the third peripheral circuit contact PCT3, the first peripheral circuit wiring line PCL1, the second peripheral circuit wiring line PCL2, and a third peripheral circuit wiring line PCL3 may be positioned in the same layer or in different layers.

The first bonding insulating layer 214 may be positioned on the peripheral circuit insulating layer 212. The first bonding insulating layer 214 may contain an insulating material. For example, the first bonding insulating layer 214 may contain silicon carbonitride, but is not limited thereto. As another example, the first bonding insulating layer 214 may contain at least one of silicon oxide, silicon oxynitride, silicon carbon oxynitride, and silicon nitride.

The third peripheral circuit contact PCT3 may be positioned in the peripheral circuit insulating layer 212 and the first bonding insulating layer 214. In other words, a portion of the third peripheral circuit contact PCT3 may be positioned in the peripheral circuit insulating layer 212, and the other portion may be positioned in the first bonding insulating layer 214.

The plurality of first bonding pads 221 may be positioned in the first bonding insulating layer 214. The first bonding insulating layer 214 may surround the plurality of first bonding pads 221. The first bonding insulating layer 214 may surround the side surface and lower surface of a first bonding pad 221. The upper surface of the first bonding insulating layer 214 may be positioned substantially at the same level as that of the upper surfaces of the plurality of first bonding pads 221, and the first bonding insulating layer 214 may expose the upper surfaces of the plurality of first bonding pads 221. The plurality of first bonding pads 221 may be connected to the second peripheral circuit wiring line PCL2 through the third peripheral circuit contact PCT3.

In embodiments, the peripheral circuit structure PS and the cell structure CS may be bonded by a wafer-to-wafer (W2W) hybrid bonding method to form the semiconductor device. For example, the peripheral circuit structure PS and the cell structure CS may be bonded by a hybrid copper bonding (HCB) method to form the semiconductor device. However, the bonding method of the peripheral circuit structure PS and the cell structure CS is not limited thereto, and may be variously changed.

Although not shown in the drawings, in some embodiments, the cell structure CS and the peripheral circuit structure PS may be connected in a direct bonding manner by the single through-hole via. For example, the cell structure CS and the peripheral circuit structure PS may be connected to a single through-via extending from the peripheral circuit structure PS to the cell structure CS.

Specifically, the peripheral circuit structure PS may include two surfaces facing each other. One surface of the two surfaces of the peripheral circuit structure PS may be a surface facing the cell structure CS, and the other surface of the peripheral circuit structure PS may be a surface facing the substrate 100.

Here, one surface of the peripheral circuit structure PS may refer to the front side of the peripheral circuit structure PS, and the other surface of the peripheral circuit structure PS may refer to the back side of the peripheral circuit structure PS.

Also, the cell structure CS may include one surface and another surface facing each other. One surface of the cell structure CS may be a surface facing the peripheral circuit structure PS, and another surface may be the opposite surface to one surface.

Here, one surface of the cell structure CS may refer to the back side of the cell structure CS, and another surface of the cell structure CS may refer to the front side of the cell structure CS.

In embodiments, one surface of the peripheral circuit structure PS adjacent to the cell structure CS may be a bonding surface with the cell structure CS. Also, one surface of the cell structure CS adjacent to the peripheral circuit structure PS may be a bonding surface with the peripheral circuit structure PS. In other words, one surface of the peripheral circuit structure PS and one surface of the cell structure CS may be the bonding surfaces of the peripheral circuit structure PS and the cell structure CS.

Accordingly, one surface of the peripheral circuit structure PS and one surface of the cell structure CS may constitute the interface of the peripheral circuit structure PS and the cell structure CS.

Specifically, the cell structure CS may include a second bonding insulating layer 216 which is in contact with the first bonding insulating layer 214 of the peripheral circuit structure PS. The second bonding insulating layer 216 may contain the same material as that of the first bonding insulating layer 214 which is positioned in the above-described peripheral circuit structure PS, and may be positioned on the first bonding insulating layer 214.

Inside the second bonding insulating layer 216 positioned in the cell structure CS, second bonding pads 222 may be positioned. The second bonding insulating layer 216 may surround the plurality of second bonding pads 222. The second bonding insulating layer 216 may surround the side surface and upper surface of a second bonding pads 222. The lower surface of the second bonding insulating layer 216 may be positioned substantially at the same level as that of the lower surfaces of the plurality of second bonding pads 222, and the second bonding insulating layer 216 may expose the lower surfaces of the plurality of second bonding pads 222.

The plurality of second bonding pads 222 which is positioned in the second bonding insulating layer 216 may form a metallic bond in a state where they are in direct contact with the plurality of first bonding pads 221 positioned in the first bonding insulating layer 214. The upper surfaces of the plurality of first bonding pads 221 and the lower surfaces of the plurality of second bonding pads 222 may be in contact. The plurality of first bonding pads 221 and the plurality of second bonding pads 222 may be positioned at the interface of the peripheral circuit structure PS and the cell structure CS, and may be in contact with each other.

Further, the first bonding insulating layer 214 which is positioned in the peripheral circuit structure PS and a plurality of second bonding insulating layers 216 which is positioned in the cell structure CS may be in contact with each other, thereby forming a bonding insulating layer.

Accordingly, one surface of the cell structure CS and one surface of the peripheral circuit structure PS may be bonded. In other words, the plurality of first bonding pads 221 and the first bonding insulating layer 214 which are positioned in the peripheral circuit structure PS may constitute one surface or bonding surface of the peripheral circuit structure PS, and the plurality of second bonding pads 222 and the second bonding insulating layer 216 which are positioned in the cell structure CS may constitute one surface or bonding surface of the cell structure CS.

The first bonding pads 221 of the peripheral circuit structure PS and the second bonding pads 222 of the cell structure CS may be bonded to provide an electrical connection path between the peripheral circuit structure PS and the cell structure CS. For example, cell connection wiring lines 232 connected to the components included in the cell structure CS may be connected to the peripheral circuit PC and/or the peripheral circuit wiring lines PCL1 and PCL2 included in the peripheral circuit structure PS by the first bonding pads 221 and the second bonding pads 222.

The cell structure CS may include a cell connection wiring contact 231 and a cell connection wiring line 232 positioned in the second bonding insulating layer 216. The cell connection wiring line 232 may be connected to components positioned in the cell structure CS, and the cell connection wiring contact 231 may connect the second bonding pad 222 and the cell connection wiring line 232. For example, the cell connection wiring line 232 may be connected to the plurality of memory cells including the memory transistor MT and the cell capacitor DSP positioned in a cell structure CS described below, the word line WL and the bit line BL connected thereto, and first portions AP1a and AP2a of each of the first and second active patterns AP1 and AP2.

Each of the peripheral circuit contacts PCT1, PCT2, and PCT3 and the peripheral circuit wiring lines PCL1 and PCL2 which are positioned in the peripheral circuit structure PS and the cell connection wiring contact 231 and the cell connection wiring line 232 which are positioned in the cell structure CS may contain a conductive material. For example, each may contain aluminum (Al), tungsten (W), titanium (Ti), copper (Cu), tantalum (Ta), etc. However, the present disclosure is not limited thereto.

In embodiments, the cell structure CS may include a plurality of bit lines BL, a plurality of word lines WL1 and WL2 that are positioned on the plurality of bit lines BL and extend across the plurality of bit lines BL, a plurality of active patterns AP1 and AP2 that are positioned between the plurality of word lines WL1 and WL2, a storage contact BC that is positioned on the plurality of active patterns AP1 and AP2, a landing pad LP positioned on the storage contact BC, the cell capacitor DSP that is positioned on the landing pad LP.

The semiconductor device according to embodiments may include the plurality of bit lines BL. The plurality of bit lines BL may extend in parallel with each other in a second direction Y intersecting a first direction X that is parallel to the substrate 100. The plurality of bit lines BL may be positioned on the substrate 100 so as to be spaced apart from each other in the first direction X.

Although not shown in detail, the plurality of bit lines BL may extend in the second direction Y from the cell array region CAR to the peripheral circuit region PAR. Accordingly, an end portion of the bit line BL may be positioned in the peripheral circuit regions PAR positioned on both sides of the cell array region CAR in the second direction Y.

The end portion of the bit line BL which is positioned in the peripheral circuit region PAR may be connected to a bit line contact (not shown in the drawings) that connects the bit line BL to the peripheral circuit structure PS.

The bit line BL may include a polysilicon layer 161, a first metal layer 163, a second metal layer 165, and a bit line capping layer 167.

The polysilicon layer 161 may contain polysilicon doped with an impurity, and the first metal layer 163 and the second metal layer 165 may contain a conductive material. For example, the first metal layer 163 may contain a conductive metal nitride (for example, titanium nitride, nitride tantalum, and the like), and the second metal layer 165 may contain a metal (for example, tungsten, titanium, tantalum, and the like).

Also, any one of the first metal layer 163 and the second metal layer 165 may contain metal silicide such as titanium silicide, cobalt silicide, or nickel silicide. However, the materials which are contained in the first metal layer 163 and the second metal layer 165 are not limited thereto, and may be variously changed.

The bit line capping layer 167 may contain an insulating material such as silicon nitride or silicon oxynitride.

In some embodiments, the bit lines BL may contain a two-dimensional or three-dimensional material, and may contain, for example, graphene which is a carbon-based two-dimensional material, carbon nanotube which is a three-dimensional material, or a combination thereof.

In embodiments, as illustrated in FIGS. 3 and 4, the plurality of bit lines BL may be positioned adjacent to the peripheral circuit structure PS. As the plurality of bit lines BL is positioned adjacent to the peripheral circuit structure PS, electrical connection paths between the bit lines BL and peripheral circuits PC may decrease.

The semiconductor device according to embodiments may further include a shield pattern SP and a spacer insulating layer 175 which are positioned between the peripheral circuit structure PS and the cell structure CS.

The shield pattern SP may be positioned between the peripheral circuit structure PS and the bit line BL. Further, the shield pattern SP may be positioned between adjacent the bit lines BL and may extend in the second direction Y. In other words, the shield pattern SP may be arranged alternately with the bit lines BL in the first direction X.

The spacer insulating layer 175 may be positioned conformally on the bit lines BL. The spacer insulating layer 175 may cover both side surfaces and the upper surface of each of the plurality of bit lines BL. The spacer insulating layer 175 may define a gap region between the plurality of bit lines BL. The gap region of the spacer insulating layer 175 may extend in the second direction Y so as to be in parallel with the bit line BL.

The shield pattern SP may contain a conductive material. For example, the shield pattern SP may include metallic materials such as tungsten (W), titanium (Ti), nickel (Ni), and cobalt (Co). As another example, the shield pattern SP may contain a conductive two-dimensional 2D material such as graphene. However, the shield pattern SP is not limited thereto.

The spacer insulating layer 175 may contain an insulating material. For example, the spacer insulating layer 175 may contain silicon oxide, silicon nitride, silicon oxynitride, and/or low-dielectric material.

The shield pattern SP may be positioned on the spacer insulating layer 175. The shield pattern SP may be positioned in the gap region of the spacer insulating layer 175.

As shown in FIG. 1 and FIG. 3, the shield pattern SP may include line portions which are positioned between the bit lines BL adjacent to each other, and a connection portion that connects the line portions in common.

Specifically, a line portion of the shield pattern SP may be positioned between bit lines BL and positioned in a plurality of gap regions defined by the spacer insulating layer 175. Accordingly, the line portions of the shield pattern SP and the side surfaces of the bit lines BL may be spaced apart with the spacer insulating layer 175 interposed therebetween.

The connection portion of the shield pattern SP may be connected to the line portions and integrated with the line portions. The connection portion of the shield pattern SP may be positioned on the line portions so as to connect line portions, and positioned between the bit lines BL adjacent to each other. However, the present disclosure is not limited thereto, and in some embodiments, the line portions and connection portions of the shield pattern SP may be formed as separate components.

Although not shown in detail, the line portion of the shield pattern SP may be positioned in the cell array region CAR and the peripheral circuit region PAR. In other words, the line portion of the shield pattern SP may extend from the cell array region CAR to the peripheral circuit region PAR. Accordingly, an end portion of the line portion of the shield pattern SP may be positioned in the peripheral circuit region PAR positioned on both sides of the second direction Y of the cell array region CAR.

Although not shown in detail, the connection portion of the shield pattern SP may extend from the cell array region CAR to the peripheral circuit region PAR. Accordingly, an end portion of the connection portion of the shield pattern PS may be positioned in the peripheral circuit region PAR. The connection portion of the shield pattern SP which is positioned in the peripheral circuit region PAR may be connected to a bit line shield contact (not shown in the drawings).

The semiconductor device according to embodiments may further include a shield capping layer 179 which is positioned on the shield pattern SP, a first cell insulating layer 177 which is positioned between the spacer insulating layer 175 and a second bonding insulating layer 216, a second cell insulating layer 173 which is positioned on the spacer insulating layer 175, and an element isolation layer STI which is positioned on the second cell insulating layer 173.

The shield capping layer 179 may be positioned between the shield pattern SP and the second bonding insulating layer 216 so as to cover the shield pattern SP.

The first cell insulating layer 177 may be positioned on the second bonding insulating layer 216. An upper surface of the first cell insulating layer 177 may be in contact with the spacer insulating layer 175, and a side surface of the first cell insulating layer 177 may be in contact with the end portion of the shield pattern SP and an end portion of the shield capping layer 179.

The second cell insulating layer 173 may be positioned on the spacer insulating layer 175.

The second cell insulating layer 173 may be in contact with the end portion of the bit line BL, and cover the end portion of the bit line BL. However, this is an example, and the second cell insulating layer 173 may be positioned apart from the end portion of the bit line BL.

The element isolation layer STI may be positioned on the second cell insulating layer 173. A portion of the element isolation layer STI may overlap the bit line BL in the third direction Z perpendicular to the bit line BL.

The shield capping layer 179, the first cell insulating layer 177, the second cell insulating layer 173, and the element isolation layer STI may contain silicon oxide, silicon nitride, silicon oxynitride, and/or a low-dielectric material. For example, the shield capping layer 179 may contain silicon nitride, and the first cell insulating layer 177, the second cell insulating layer 173, and the element isolation layer STI may contain silicon oxide. However, this is an example, and the materials which is contained in each of the shield capping layer 179, the first cell insulating layer 177, the second cell insulating layer 173, and the element isolation layer STI may be variously changed.

The plurality of word lines WL1 and WL2 may be positioned on the bit lines BL and the shield pattern SP.

The plurality of word lines WL1 and WL2 may include a plurality of first word lines WL1 and a plurality of second word lines WL2 which extend in the first direction X intersecting the second direction Y which is the extension direction of the bit lines BL. The plurality of first word lines WL1 and second word lines WL2 may be positioned apart from each other in the second direction Y.

The plurality of first word lines WL1 and the plurality of second word lines WL2 may overlap the bit line BL and the shield pattern SP in the third direction Z. The plurality of first word lines WL1 and second word lines WL2 may extend in the third direction Z that intersects the first direction X and the second direction Y.

In embodiments, the word lines WL1 and WL2 have a rectangular shape in a cross-sectional view, the cross-sectional shape of the word lines WL1 and WL2 is not limited thereto, and may be variously changed. For example, each of the word lines WL1 and WL2 may have an ‘L’ shape in a cross-sectional view.

In embodiments, the word lines WL1 and WL2 may extend in the first direction X from the cell array region CAR to the peripheral circuit region PAR. Accordingly, end portions of the word lines WL1 and WL2 may be positioned in the peripheral circuit region PAR, and a word line contact 243 may be connected to the end portions.

In FIG. 1, it is shown that the word line contact 243 has a circular shape in a plan view, however, the shape is not limited thereto and may be variously modified. For example, the word line contact 243 may have various shapes such as an oval shape, a rectangular shape, a square shape, a rhombic shape, and a hexagonal shape in a plan view.

Each of the word lines WL1 and WL2 may include a first surface and a second surface facing each other in the third direction Z.

Here, the first surface of each of the word lines WL1 and WL2 may refer to the surface facing the bit line BL and the shield pattern SP, and the second surface may refer to the surface facing the storage contact BC. In other words, the first surface of each of the word lines WL1 and WL2 may correspond to the lower surface, and the second surface may correspond to the upper surface.

Each of the first and second word lines WL1 and WL2 may contain a conductive material. For example, each of the first and second word lines WL1 and WL2 may contain at least one of doped polysilicon, conductive metal nitride, conductive metal silicon nitride, metal carbon nitride, conductive metal silicide, conductive metal oxide, two-dimensional material, and metal. However, the conductive material is not limited thereto.

The plurality of active patterns AP1 and AP2 may include a plurality of first active patterns AP1 and a plurality of second active patterns AP2, which are spaced apart in the second direction Y between the word lines WL1 and WL2.

The plurality of first active patterns AP1 and the plurality of second active patterns AP2 may be positioned alternately in the second direction Y on the bit lines BL.

In embodiments, the first active pattern AP1 and the second active pattern AP2, which are positioned between the word lines WL1 and WL2, may have a symmetrical structure with respect to a separation insulating pattern 131 to be described below.

In embodiments, each of the plurality of active patterns AP1 and AP2 may include first portions AP1a and AP2a extending in a first direction X, and a plurality of second portions AP1b and AP2b protruding from the respective first portions AP1a and AP2a toward to one or the other side in a second direction Y, and positioned between one of the first portions AP1a and AP2a and a first word line WL1 or between another of the first portions AP1a and AP2a and a second word line WL2.

Specifically, the first active pattern AP1 may include a first portion AP1a extending in the first direction X, and a plurality of second portions AP1b protruding from the first portion AP1a toward one side in the second direction Y, and positioned between the first portion AP1a and the first word line WL1.

Further, the second active pattern AP2 may include a first portion AP2a extending in the first direction X, and a plurality of second portions AP2b protruding from the first portion AP2a toward the other side in the second direction Y, and positioned between the first portion AP2a and the second word line WL2.

Each of the first portions AP1a and AP2a of the active patterns AP1 and AP2 may extend in the first direction X, which is the extension direction of the word lines WL1 and WL2, and may have a line shape in a plan view.

As shown in FIG. 1, in embodiments, each of the first portions AP1a and AP2a of the active patterns AP1 and AP2 may extend in the first direction X from the cell array region CAR to the peripheral circuit region PAR. For example, end portions of the first portions AP1a and AP2a of the active patterns AP1 and AP2 may be positioned in the peripheral circuit region PAR positioned on both sides of the first direction X of the cell array region CAR. However, the present disclosure is not limited thereto. For example, the end portions of the first portions AP1a and AP2a of the active patterns AP1 and AP2 may be positioned on either one side or the other side of the first direction X of the cell array region CAR.

Accordingly, each end portion of the first portions AP1a and AP2a of the active patterns AP1 and AP2 may be electrically connected to the peripheral circuit structure PS through the active pattern contact 241 positioned in the peripheral circuit region PAR.

In FIG. 1, it is shown that the active pattern contact 241 has a circular shape in a plan view, however, the shape is not limited thereto and may be variously modified. For example, the active pattern contact 241 may have various shapes such as an oval shape, a rectangular shape, a square shape, a rhombic shape, and a hexagonal shape in a plan view.

The active pattern contact 241 may contain a conductive material. For example, the active pattern contact 241 may contain a conductive material such as aluminum (Al), tungsten (W), titanium (Ti), copper (Cu), or tantalum (Ta), but is not limited thereto.

A detailed description of the active pattern contact 241 connected to the active patterns AP1 and AP2 will be provided below.

As shown in FIG. 1, in embodiments, a length of each of the active patterns AP1 and AP2 in the first direction X may differ from a length of each of the word lines WL1 and WL2 in the first direction X. For example, a length of the first portion AP1a of the first active pattern AP1 in the first direction X may be longer than a length of the first word line WL1 in the first direction X, and a length of the first portion AP2a of the second active pattern AP2 in the first direction X may be longer than a length of the second word line WL2 in the first direction X. In other words, in the peripheral circuit region PAR, the end portions of the first portions AP1a and AP2a of the active patterns AP1 and AP2 may protrude farther in the first direction X than the end portions of the word lines WL1 and WL2.

Accordingly, the number and arrangement relationship of the plurality of active pattern contacts 241 and the plurality of word line contacts 243, which are connected to the end portions of the plurality of active patterns AP1 and AP2 and the plurality of word lines WL1 and WL2, respectively, may be variously changed.

Unlike FIG. 1, in some embodiments, the relationship between the lengths of the active patterns AP1 and AP2 in the first direction X and the lengths of the word lines WL1 and WL2 in the first direction X may be variously changed. For example, the length each of the active patterns AP1 and AP2 in the first direction X may be shorter than or substantially equal to the length each of the word lines WL1 and WL2 in the first direction X.

As shown in FIG. 1, in embodiments, some of the active pattern contacts 241 may be connected to end portions of some of the active patterns AP1 and AP2 in the peripheral circuit region PAR positioned on one side of the first direction X, and the remaining active pattern contacts 241 may be connected to end portions of the remaining active patterns AP1 and AP2 in the peripheral circuit region PAR positioned on the other side of the first direction X. For example, the plurality of active pattern contacts 241 may be connected to end portions of the first portions AP1a and AP2a of the active patterns AP1 and AP2 positioned in the peripheral circuit region PAR.

Further, some of the word line contacts 243 may be connected to end portions of some of the word lines WL1 and WL2 in the peripheral circuit region PAR positioned on one side of the first direction X, and the remaining word line contacts 243 may be connected to end portions of the remaining word lines WL1 and WL2 in the peripheral circuit region PAR positioned on the other side of the first direction X.

Accordingly, some of the active pattern contacts 241 and some of the word line contacts 243 may be positioned in the peripheral circuit region PAR positioned on one side of the first direction X, and the remaining active pattern contacts 241 and the remaining word line contacts 243 may be positioned in the peripheral circuit region PAR positioned on the other side of the first direction X. However, the number and arrangement of each of the plurality of active pattern contacts 241 and the plurality of word line contacts 243 are not limited thereto and may be variously changed.

Unlike FIG. 1, in some embodiments, the active pattern contacts 241 and the word line contacts 243 may be connected to the end portions of the active patterns AP1 and AP2 and the word lines WL1 and WL2, respectively, in the peripheral circuit region PAR positioned on either side of the first direction X.

Accordingly, the plurality of active pattern contacts 241 and the plurality of word line contacts 243 may be positioned on only one side or the other side of the first direction X.

Further, in some embodiments, the plurality of active pattern contacts 241 and the plurality of word line contacts 243 may be connected to end portions of the active patterns AP1 and AP2 and end portions of the word lines WL1 and WL2, respectively, in the peripheral circuit regions PAR positioned on opposite sides of the first direction X.

Accordingly, the plurality of active pattern contacts 241 and the plurality of word line contacts 243 may be positioned in both peripheral circuit regions PAR positioned on both sides of the first direction X. In other words, the plurality of active pattern contacts 241 may be connected to end portions on both sides of the active patterns AP1 and AP2 positioned on both sides in the first direction X, and the plurality of word line contacts 243 may be connected to end portions on both sides of the word lines WL1 and WL2 positioned on both sides in the first direction X.

In embodiments, the end portions of the first portions AP1a and AP2a of the active patterns AP1 and AP2 may contact the element isolation layer STI in the peripheral circuit region PAR. However, the present disclosure is not limited thereto. For example, another component may be further positioned between the end portions of the first portions AP1a and AP2a of the active patterns AP1 and AP2 and the element isolation layer STI.

In embodiments, the plurality of second portions AP1b of the first active pattern AP1 may be spaced apart in the first direction X. Each of the plurality of second portions AP1b of the first active pattern AP1 has a shape that protrudes from a side surface of the first portion AP1a toward one side in the second direction Y in a plan view, and each of the side surfaces of the plurality of second portions AP1b may be surrounded by the first word line WL1.

Further, the plurality of second portions AP2b of the second active pattern AP2 may be spaced apart from each other in the first direction X. Each of the second portions AP2b of the second active pattern AP2 may be spaced apart from each of the second portions AP1b of the first active pattern AP1, with the first portion AP1a of the first active pattern AP1 and the first portion AP2a of the second active pattern AP2 interposed therebetween. For example, in a plan view, each of the second portions AP1b of the first active pattern AP1 may have a symmetrical structure, with the second portions AP2b of the second active pattern AP2 and the first portions AP1a and AP2a of the active patterns AP1 and AP2 interposed therebetween.

Each of the plurality of second portions AP2b of the second active pattern AP2 has a shape that protrudes from a side surface of the first portion AP2a toward the other side in the second direction Y in a plan view, and each of the side surfaces of the plurality of second portions AP1b may be surrounded by the second word line WL2.

Specifically, as shown in FIG. 2, each of the word lines WL1 and WL2 may include gate line portions WL1_B and WL2_B extending in a first direction X, and gate protrusion portions WL1_P and WL2_P extending in a second direction Y from the gate line portions WL1_B and WL2_B.

The first word line WL1 may include a first gate line portion WL1_B extending in the first direction X, and a plurality of first gate protrusion portions WL1_P extending in the second direction Y from the first gate line portion WL1_B and positioned between second portions AP1b of the first active patterns AP1 adjacent to each other in the first direction X.

Further, the second word line WL2 may include a second gate line portion WL2_B extending in the first direction X, and a plurality of second gate protrusion portions WL2_P extending in the second direction Y from the second gate line portion WL2_B and positioned between second portions AP2b of second active patterns AP2 adjacent to each other in the first direction X.

Accordingly, each of the second portions AP1b and AP2b of the active patterns AP1 and AP2 may be surrounded by gate line portions WL1_B and WL2_B and gate protrusion portions WL1_P and WL2_P of the word lines WL1 and WL2 in a plan view.

In a plan view, the side surfaces of each of the first portions AP1a and AP2a of the active patterns AP1 and AP2 may face the gate protrusion portions WL1_P and WL2_P of the word lines WL1 and WL2. However, the planar shape of the word lines WL1 and WL2 is not limited thereto, and may be variously changed. For example, when the gate protrusion portions WL1_P and WL2_P are omitted, each of the word lines WL1 and WL2 may have a line shape in a plan view.

In embodiments, each of the active patterns AP1 and AP2 may contain a monocrystalline semiconductor material. For example, the active patterns AP1 and AP2 may contain single crystal silicon. However, the present disclosure is not limited thereto, and the materials which are contained in the active patterns AP1 and AP2 may be variously changed. For example, the active patterns AP1 and AP2 may contain at least one of polycrystalline semiconductors, oxide semiconductors, and two-dimensional materials. For example, a polycrystalline semiconductor may be polysilicon. As another example, an oxide semiconductor may be indium gallium zinc oxide (IGZO). As a further example, a two-dimensional material may be MoS₂, WS₂, MoSe₂, or WSe₂.

In embodiments, the first portion AP1a and the second portion AP1b of the first active pattern AP1 may be formed together in the same process using the same material, and a boundary between them may not be visually distinguishable. For example, the first portion AP1a and the second portion AP1b of the first active pattern AP1 may contain single crystal silicon, and a boundary between them may not be visually distinguishable. However, the present disclosure is not limited thereto, the first portion AP1a and the second portion AP1b of the first active pattern AP1 may contain different materials and may be formed in separate process, so that a boundary between them may be visually distinguishable.

The above description has been provided with reference to the first portion AP1a and the second portion AP1b of the first active pattern AP1. However, the same or substantially the same explanation may also be applied to the first portion AP2a and the second portion AP2b of the second active pattern AP2, and thus a detailed description thereof will not be made.

A detailed description of the active patterns AP1 and AP2 and the components adjacent to them is described below with reference to FIG. 5.

The active patterns AP1 and AP2 may each have a length in a first direction X, a width in a second direction Y, and a height in a third direction Z. Each of the active patterns AP1 and AP2 may include a first surface and a second surface facing each other in the third direction Z.

Here, the first surface may refer to the surface adjacent to the bit line BL, and the second surface may refer to the surface adjacent to the storage contact BC to be described below. In other words, the first surface of the active patterns AP1 and AP2 may refer to the lower side, and the second surface may refer to the upper surface.

The semiconductor device according to embodiments may further include a gate insulating pattern GOX positioned between the plurality of active patterns AP1 and AP2 and the plurality of word lines WL1 and WL2, a gate separation pattern 141 positioned between adjacent word lines WL1 and WL2, a first gate capping pattern 143 positioned on the second surface of the word lines WL, and a second gate capping pattern 145 positioned on a first surface of the word lines WL.

A gate insulating pattern GOX may be positioned between the first active pattern AP1 and the first word line WL1, and between the second active pattern AP2 and the second word line WL2.

One side surface of the gate insulating pattern GOX may extend in the third direction Z along side surfaces of the active patterns AP1 and AP2, and the other side surface may extend in the third direction Z along side surfaces of the word lines WL1 and WL2.

The gate separation pattern 141 may be positioned between the word lines WL1 and WL2 spaced apart in the second direction Y. The word lines WL1 and WL2 may be separated and insulated by a gate separation pattern 141.

The gate separation pattern 141 may extend in the third direction Z between the word lines WL1 and WL2. The gate separation pattern 141 may be positioned between the first gate capping pattern 143 and a contact interlayer insulating layer 271, which will be described below.

In embodiments, the gate separation pattern 141 may include a first surface and a second surface facing each other in the third direction Z.

Here, the first surface of the gate separation pattern 141 may refer to a surface adjacent to the bit line BL, and the second surface may refer to a surface adjacent to the storage contact BC. In other words, the first surface of the gate separation pattern 141 may refer to the lower surface, and the second surface may refer to the upper surface.

A length of the gate separation pattern 141 in the third direction Z may be longer than the lengths of the word lines WL1 and WL2 in the third direction Z. The first surface of the gate separation pattern 141 may be positioned at a lower level than the first surface of the word lines WL1 and WL2, and the second surface may be positioned at a higher level than the second surface of the word lines WL1 and WL2. However, the present disclosure is not limited thereto, and the relationship between the length of the gate separation pattern 141 in a third direction Z and the lengths of the word lines WL1 and WL2 in the third direction Z may be variously changed.

The first gate capping pattern 143 may be positioned on the second surface of each of the word lines WL1 and WL2, and may cover the second surface of each of the word lines WL1 and WL2. The first gate capping pattern 143 may be positioned between a contact interlayer insulating layer 271, which will be described below, and the word lines WL1 and WL2. Also, the first gate capping pattern 143 may be positioned between the storage contact BC, which will be described below, and the word lines WL1 and WL2.

The second gate capping pattern 145 may be positioned on the first surface of each of the word lines WL1 and WL2, and may cover the first surface each of the word lines WL1 and WL2.

The second gate capping pattern 145 may be positioned between the word lines WL1 and WL2 and the bit line BL. The second gate capping pattern 145 may cover the first surface of the gate separation pattern 141 and the side surface of the gate separation pattern 141 adjacent thereto.

Both side surfaces of each of the first gate capping pattern 143 and the second gate capping pattern 145 may be covered by a gate insulating pattern GOX. In other words, the gate insulating pattern GOX may extend in the third direction Z along each surface of the first gate capping pattern 143 and the second gate capping pattern 145.

The gate insulating pattern GOX may contain silicon oxide, silicon oxynitride, a high-dielectric constant material having a dielectric constant higher than that of silicon oxide, or a combination thereof. For example, the high-dielectric constant material may contain any one of HfO₂, HfSiO, HfSiON, HfTaO, HfTiO, HfZrO, ZrO₂, Al2O₃, or combinations thereof, but is not limited thereto.

Each of the gate separation pattern 141, the first gate capping pattern 143, and the second gate capping pattern 145 may contain any one of silicon oxide, silicon nitride, or a combination thereof. For example, the gate separation pattern 141 may cotain silicon oxide, and the first gate capping pattern 143 and the second gate capping pattern 145 may include silicon nitride. However, the present disclosure is not limited thereto.

The semiconductor device according to embodiments may further include the separation insulating pattern 131 positioned between adjacent active patterns AP1 and AP2.

In the cell array region CAR, the separation insulating pattern 131 may extend in the first direction X between the first active pattern AP1 and the second active pattern AP2, which are adjacent to each other in the second direction Y. The separation insulating pattern 131 may separate and insulate the first active pattern AP1 and the second active pattern AP2, which are adjacent to each other.

Specifically, the separation insulating pattern 131 may be positioned between the first portion AP1a of the first active pattern AP1 and the first portion AP2a of the second active pattern AP2.

The separation insulating pattern 131 may be in contact with the first portion AP1a of the first active pattern AP1 and the first portion AP2a of the second active pattern AP2. However, the present disclosure is not limited thereto, and another component may be further positioned between the separation insulating pattern 131 and the active patterns AP1 and AP2.

The separation insulating pattern 131 may extend in the third direction Z between the first active pattern AP1 and the second active pattern AP2. The separation insulating pattern 131 may be positioned between the contact interlayer insulating layer 271, which will be described below, and the bit line BL

In embodiments, a length of the separation insulating pattern 131 in the third direction Z may be substantially equal to the length of each of the active patterns AP1 and AP2 in the third direction Z. For example, the length of the separation insulating pattern 131 in the third direction Z may be substantially the same as the length of each of the first portions AP1a and AP2a of the active patterns AP1 and AP2 in the third direction Z.

Here, the length of the separation insulating pattern 131 in the third direction Z and the length of each of the first portions AP1a and AP2a of the active patterns AP1 and AP2 in the third direction Z may refer to a maximum length in the third direction Z. However, the present disclosure is not limited thereto, and the relationship between the length of the separation insulating pattern 131 in a third direction Z and the length each of the active patterns AP1 and AP2 in the third direction Z may be variously changed.

The separated insulating pattern 131 may contain an insulating material. For example, the separated insulating pattern 131 may contain any one of silicon oxide, silicon nitride, or a combination thereof. However, the present disclosure is not limited thereto, and the material of the separation insulating pattern 131 may be variously changed.

In embodiments, the separated insulating pattern 131 is illustrated as having a single-layer structure. However, the present disclosure is not limited thereto, and the separated insulating pattern 131 may have a multi-layer structure including the same material and/or different materials.

The semiconductor device according to embodiments may further include the contact interlayer insulating layer 271, a pad separation insulating layer 273, and a contact etch stop layer 275 sequentially stacked on the active patterns AP1 and AP2.

The contact interlayer insulating layer 271 may be positioned on the active patterns AP1 and AP2. The contact interlayer insulation layer 271 may cover the gate separation pattern 141, the first gate capping pattern 143, and the element isolation layer STI.

The pad separation insulating layer 273 and the contact etch stop layer 275 may be sequentially positioned on the contact interlayer insulating layer 271.

The contact interlayer insulating layer 271, the pad separation insulating layer 273, and the contact etch stop layer 275 may contain silicon oxide, silicon nitride, or a combination thereof. For example, the contact interlayer insulating layer 271 may contain silicon oxide, and the pad separation insulating layer 273 and the contact etch stop layer 275 may contain silicon nitride. However, the present disclosure is not limited thereto.

In the cell array region CAR of the cell structure CS, the storage contact BC, the landing pad LP, and the cell capacitor DSP may be sequentially stacked.

The semiconductor device according to embodiments may include a plurality of storage contacts BC. The plurality of storage contacts BC may pass through the contact interlayer insulating layer 271. The plurality of storage contacts BC may be connected to the first and second active patterns AP1 and AP2, respectively.

Storage contacts BC adjacent to each other may be separated and insulated from each other by the contact interlayer insulating layer 271. An upper surface of the storage contact BC may be positioned at substantially the same level as the upper surface of the contact interlayer insulating layer 271.

The plurality of storage contacts BC may be arranged in a matrix pattern along the first direction X and the second direction Y on a plane.

In FIG. 1, it is shown that each storage contact BC has a circular shape in a plan view. however, the present disclosure is not limited thereto, and each storage contact BC may have various shapes such as an oval shape, a rectangular shape, a square shape, a rhombic shape, and a hexagonal shape in a plan view.

In embodiments, the storage contact BC may overlap the active patterns AP1 and AP2, the gate insulating pattern GOX, and the first gate capping pattern 143 in the third direction Z, and may not overlap the separation insulating pattern 131 in the third direction Z.

The storage contact BC may recess the active patterns AP1 and AP2, the gate insulating pattern GOX, and the first gate capping pattern 143. However, the arrangement of the storage contact BC is not limited thereto and may be variously changed. For example, at least a portion of the storage contact BC may be positioned to overlap the separation insulating pattern 131 in the third direction Z.

The storage contact BC may contain a conductive material. For example, the conductive material may contain at least one of doped polysilicon, conductive metal nitride, conductive metal silicon nitride, metal carbonitride, conductive metal silicide, conductive metal oxide, two-dimensional material, and metal.

The semiconductor device according to embodiments may include a plurality of landing pads LP. The plurality of landing pads LP may be positioned on the plurality of storage contacts BC, respectively.

The plurality of landing pads LP may be arranged in a matrix form along the first direction X and the second direction Y in a plan view.

In FIG. 1, it is shown that each landing pad LP has a circular shape in a plan view. however, the present disclosure is not limited thereto, and each landing pad LP may have various shapes such as an oval shape, a rectangular shape, a square shape, a rhombic shape, and a hexagonal shape in a plan view.

Between the landing pads LP, pad separation insulating layers 273 may be positioned. The upper surface of the landing pad LP may be positioned substantially at the same level as that of the upper surface of the pad separation insulating layer 273.

Unlike FIGS. 3 and 4, in some embodiments, the landing pad LP may be omitted. when the landing pad LP is omitted, the pad separation insulating layer 273 surrounding the landing pad LP may also be omitted. Accordingly, the storage contact BC and the cell capacitor DSP may be directly connected.

The landing pad LP may contain a conductive material. The conductive material may contain, for example, at least one of doped polysilicon, conductive metal nitride, conductive metal silicon nitride, metal carbonitride, conductive metal silicide, conductive metal oxide, two-dimensional material, and metal.

The semiconductor device according to embodiments may include a plurality of cell capacitors DSP. The plurality of cell capacitors DSP may be arranged in a matrix pattern along the first direction X and the second direction Y, as shown in FIG. 1.

The plurality of cell capacitors DSP may be positioned on the plurality of landing pads LP, respectively. The plurality of cell capacitors DSP may entirely or partially overlap the plurality of landing pads LP in the third direction Z, respectively. The plurality of cell capacitors DSP may be connected to the first and second active patterns AP1 and AP2, respectively.

Each cell capacitor DSP may include a first electrode 251, a second electrode 255, and a dielectric film 253 which is positioned between the first electrode 251 and the second electrode 255.

The first electrode 251 may pass through the contact etch stop layer 275 and be connected to the landing pad LP. The first electrode 251 may extend in the third direction Z on the landing pad LP.

The first electrode 251 may contain a metal, a conductive metal nitride, or a combination thereof. For example, the first electrode 251 may consist of TiN, Ru, TaN, WN, Pt, Ir, or a combination thereof. However, the material which is contained in the first electrode 251 is not limited thereto, and may be variously changed.

The dielectric film 253 may extend so as to conform to the profile of the upper surface and side surfaces of the first electrode 251. In other words, the dielectric film 253 may cover the side surfaces and upper surface of the first electrode 251. A portion of the dielectric film 253 may be positioned on the upper surface of the contact etch stop layer 275. In other words, a portion of the dielectric film 253 may be positioned between the contact etch stop layer 275 and the second electrode 255.

The dielectric film 253 may contain tantalum oxide (Ta₂O₅), aluminum oxide (Al₂O₃), titanium oxide (TiO₂), or a combination thereof. However, the present disclosure is not limited thereto, and the material which is contained in the dielectric film 253 may be variously changed.

The second electrode 255 may be positioned on the dielectric film 253. The second electrode 255 may entirely cover the first electrode 251. In other words, the second electrode 255 may cover the upper surface and side surfaces of the first electrode 251.

The second electrode 255 may contain a metal material such as W, Ti, Ru, SiGe, etc. For example, the second electrode 255 may contain tungsten (W). However, the material which is contained in the second electrode 255 is not limited thereto, and may be variously changed. For example, the second electrode 255 may contain conductive metal nitride, metal silicide, or a combination thereof.

The semiconductor device according to embodiments may further include a third cell insulating layer 277 and a fourth cell insulating layer 279 sequentially stacked on the contact etch stop layer 275.

Also, the semiconductor device according to embodiments may further include a first cell wiring contact 261 and a first cell wiring line 262 which are positioned inside the third cell insulating layer 277, and a second cell wiring contact 263 and a second cell wiring line 264 which are positioned inside the fourth cell insulating layer 279.

The third cell insulating layer 277 may entirely cover the cell capacitor DSP. In other words, the third cell insulating layer 277 may cover the upper surface and side surfaces of the cell capacitor DSP.

The cell capacitor DSP may be connected to the first cell wiring line 262 through the first cell wiring contact 261, and the first cell wiring line 262 may be connected to the second cell wiring line 264 through the second cell wiring contact 263.

In embodiments, the first cell wiring line 262 may be a wiring line to which an external voltage is applied, or a redistribution layer (RDL) connected to a wiring line to which a voltage is applied. At least a portion of the second cell wiring line 264 may correspond to a power line to which an external voltage is applied. However, this is an example, and the functions of the first cell wiring line 262 and the second cell wiring line 264 may be variously changed.

The first cell wiring contact 261, the first cell wiring line 262, the second cell wiring contact 263, and the second cell wiring line 264 may contain any one of metals, such as copper (Cu), aluminum (Al), tungsten (W), titanium (Ti), and tantalum (Ta), or combinations thereof.

Hereinafter, with further reference to FIG. 5, a detailed description will be provided regarding the arrangement relationship between the active patterns AP1 and AP2 and structures adjacent thereto.

Referring to FIG. 5, each of the first portions AP1a and AP2a of the active patterns AP1 and AP2 may extend in the third direction Z between the storage contact BC and the bit line BL.

In embodiments, each of the first portions AP1a and AP2a of the active patterns AP1 and AP2 may contact at least one of the storage contact BC and the bit line BL. For example, as shown in FIG. 5, one end portion of each of the first portions AP1a and AP2a of the active patterns AP1 and AP2 may be connected to the bit line BL, and the other end portion may be connected to the storage contact BC.

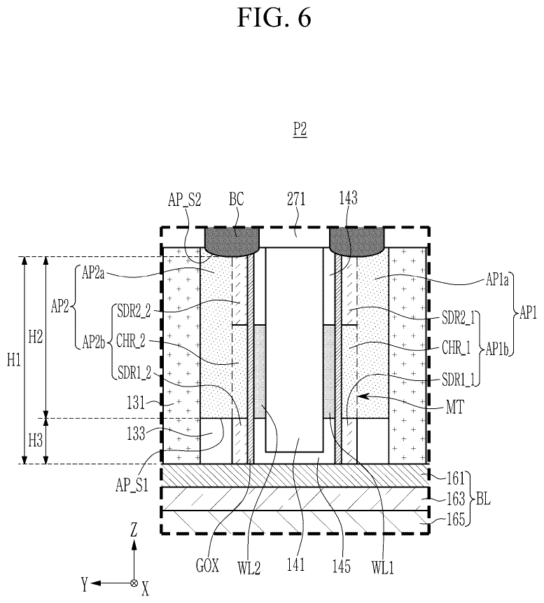

In embodiments, each of the first portions AP1a and AP2a of the active patterns AP1 and AP2 may be positioned to overlap a portion of the storage contact BC in the third direction Z. In other words, a portion of the end portion of each of the first portions AP1a and AP2a of the active patterns AP1 and AP2 may be in contact with the storage contact BC, and the remaining portion of the end portion may not be in contact with the storage contact BC. However, the present disclosure is not limited thereto, and the arrangement relationship among the first portions AP1a and AP2a of the active patterns AP1 and AP2, the bit line BL, and the storage contact BC may be variously changed. A detailed description of this is provided below with reference to FIGS. 6 to 10.

In embodiments, the second portion AP1b of the first active pattern AP1 may include a first dopant region SDR1_1 connected to the bit line BL, a second dopant region SDR2_1 connected to the storage contact BC, and a channel region CHR_1 positioned between the first dopant region SDR1_1 and the second dopant region SDR2_1.

Also, the second portion AP2b of the second active pattern AP2 may include a first dopant region SDR1_2 connected to the bit line BL, a second dopant region SDR2_2 connected to the storage contact BC, and a channel region CHR_2 positioned between the first dopant region SDR1_2 and the second dopant region SDR2_2.

In embodiments, each of the first portions AP1a and AP2a of the active patterns AP1 and AP2 corresponds to a body of a memory transistor MT, in which excess holes generated by operation of the memory transistor MT or by impact ionization that generates electron-hole pairs may be accumulated. Further, the first dopant regions SDR1_1 and SDR1_2 of the active patterns AP1 and AP2 may correspond to a first source/drain electrode of the memory transistor MT, and the second dopant regions SDR2_1 and SDR2_2 may correspond to a second source/drain electrode, and the channel regions CHR_1 and CHR_2 may correspond to a channel of the memory transistor MT.

The first and second dopant regions SDR1_1, SDR1_2, SDR2_1, and SDR2_2 are regions doped with dopants in each of the active patterns AP1 and AP2, and the dopant concentration included in each of the first and second dopant regions SDR1_1, SDR1_2, SDR2_1, and SDR2_2 may be greater than the dopant concentration included in each of the channel regions CHR_1 and CHR_2.

Specifically, each of the channel regions CHR_1 and CHR_2 included in the second portions AP1b and AP2b of the active patterns AP1 and AP2 may extend in a third direction Z, which is perpendicular to the substrate 100, and may be positioned to overlap the word lines WL1 and WL2 connected to a gate electrode of the memory transistor MT, and may constitute vertical channels.

The first dopant regions SDR1_1 and SDR1_2 included in each of the second portions AP1b and AP2b of the active patterns AP1 and AP2 may extend in a third direction Z between each of the channel regions CHR_1 and CHR_2 and the bit line BL, and the second dopant regions SDR2_1 and SDR2_2 may extend in a third direction Z between each of the channel regions CHR_1 and CHR_2 and the storage contact BC.

In embodiments, each end portion of the second dopant regions SDR2_1 and SDR2_2 included in the second portions AP1b and AP2b of the active patterns AP1 and AP2 may be entirely in contact with the storage contact BC. In other words, each of the second dopant regions SDR2_1 and SDR2_2 may entirely overlap the storage contact BC in the third direction Z. However, this is not limited thereto, and a portion of each of the second dopant regions SDR2_1 and SDR2_2 may overlap the storage contact BC in the third direction Z, and a remaining portion of each of the second dopant regions SDR2_1 and SDR2_2 may not overlap the storage contact BC in the third direction Z.

In embodiments, the active patterns AP1 and AP2 may be recessed by the storage contact BC. For example, as shown in FIG. 5, a portion of one surface of each of the first portions AP1a and AP2a of the active patterns AP1 and AP2 that is in contact with the storage contact BC may be recessed by the storage contact BC to have a curved shape, and the remaining portion may have a straight shape.

Also, one surface of each of the second portions AP1b and AP2b of the active patterns AP1 and AP2 that is in contact with the storage contact BC may be recessed by the storage contact BC to have entirely a curved shape. However, the shapes of each of the first portions AP1a and AP2a and the second portions AP1b and AP2b of the active patterns AP1 and AP2 are not limited thereto, and may be variously changed.

Unlike in FIG. 5, in some embodiments, one surface of each of the first portions AP1a and AP2a of the active patterns AP1, AP2 that is in contact with the storage contact BC may be recessed by the storage contact BC to have entirely a curved shape.

Further, in some embodiments, since the storage contact BC does not recess the active patterns AP1 and AP2, one surface of each of the first portions AP1a and AP2a, and one surface of each of the second portions AP1b and AP2b of the active patterns AP1 and AP2 that are in contact with the storage contact BC may have entirely a straight shape.

In embodiments, the first portions AP1a and AP2a of the active patterns AP1 and AP2, and the channel regions CHR_1 and CHR_2 included in the second portions AP1b and AP2b may include a first dopant. Also, the first and second dopant regions SDR1_1, SDR1_2, SDR2_1, and SDR2_2 included in the second portions AP1b and AP2b may include a second dopant that is different from the first dopant.

Specifically, the first dopant may be a p-type dopant, such as aluminum (Al), boron (B), indium (In), gallium (Ga), or a combination thereof, and the second dopant may be an n-type dopant, such as phosphorus (P), arsenic (As), bismuth (Bi), antimony (SB), or a combination thereof. However, the first dopant and the second dopant are not limited thereto and may be variously changed. For example, the first dopant may be an n-type dopant and the second dopant may be a p-type dopant.

In some embodiments, the first portions AP1a and AP2a of the active patterns AP1 and AP2, and the channel regions CHR_1 and CHR_2 included in the second portions AP1b and AP2b may not be doped with dopants.

In embodiments, the first portions AP1a and AP2a of the active patterns AP1 and AP2, and the channel regions CHR_1 and CHR_2 of the second portions AP1b and AP2b may include the same dopant, and a concentration of the dopant included in each of the first portions AP1a and AP2a may be different from a concentration of the dopant included in each of the channel regions CHR_1 and CHR_2. For example, a concentration of the dopant included in the first portion AP1a of the first active pattern AP1 may be different from a concentration of the dopant included in the channel region CHR_1 of the second portion AP1b of the first active pattern AP1, and a concentration of the dopant included in the first portion AP2a of the second active pattern AP2 may be different from a concentration of the dopant included in the channel region CHR_2 of the second portion AP2b of the second active pattern AP2.

Specifically, as described above, the first portions AP1a and AP2a of the active patterns AP1 and AP2, and the channel regions CHR_1 and CHR_2 of the second portions AP1b and AP2b may include the p-type dopant, and a concentration of the p-type dopant included in each of the first portions AP1a and AP2a may be greater than a concentration of the p-type dopant included in each of the channel regions CHR_1 and CHR_2. In other words, a concentration of the p-type dopant included in the first portion AP1a of the first active pattern AP1 may be greater than a concentration of the p-type dopant included in the channel region CHR_1 of the second portion AP1b of the first active pattern AP1, and a concentration of the p-type dopant included in the first portion AP2a of the second active pattern AP2 may be greater than a concentration of the p-type dopant included in the channel region CHR_2 of the second portion AP2b of the second active pattern AP2.

In embodiments, when a voltage applied to the word lines WL1 and WL2, which are connected to the gate electrode of the memory transistor MT, exceeds a threshold voltage (Vₜₕ), channel regions CHR_1 and CHR_2 may be formed, respectively, in the second portions AP1b and AP2b of the active patterns AP1 and AP2, which overlap the word lines WL1 and WL2, respectively, and the threshold voltage may be determined based on a concentration of a dopant included in the active patterns AP1 and AP2.

As described above, when the concentration of the p-type dopant included in each of the first portions AP1a and AP2a of the active patterns AP1 and AP2 is greater than the concentration of the p-type dopant included in each of the channel regions CHR_1 and CHR_2 of the second portions AP1b and AP2b, a threshold voltage of the first portions AP1a and AP2a may relatively increase, while a threshold voltage of each of the channel regions CHR_1 and CHR_2 of the second portions AP1b and AP2b may relatively decrease.

Accordingly, when substantially the same voltage is applied to the word lines WL1 and WL2 adjacent to the first portions AP1a and AP2a and the second portions AP1b and AP2b of the active patterns AP1 and AP2, respectively, channels of the memory transistor MT may not be formed in the first portions AP1a and AP2a, which have relatively higher threshold voltages, but may be formed in the channel regions CHR_1 and CHR_2 of the second portions AP1b and AP2b, respectively, which have relatively lower threshold voltages.

More specifically, as shown in FIG. 2, the concentration of the p-type dopant included in each of the first portions AP1a and AP2a of the active patterns AP1 and AP2, which are adjacent to the gate protrusion portions WL1_P and WL2_P of word lines WL1 and WL2 in a plan view, may be greater than the concentration of the p-type dopant included in each of the second portions AP1b and AP2b of the active patterns AP1 and AP2, which are adjacent to the gate line portions WL1_B and WL2_B of the word lines WL1 and WL2. As a result, when substantially the same voltage is applied to the gate protrusion portions WL1_P and WL2_P and the gate line portions WL1_B and WL2_B, channels of the memory transistor MT may be formed only in the second portions AP1b and AP2b of the active patterns AP1 and AP2, which have relatively lower threshold voltages. In other words, channels of the memory transistor MT may be formed only in the channel regions CHR_1 and CHR_2 of the second portions AP1b and AP2b of the active patterns AP1 and AP2.

As described above, by adjusting the concentration of a dopant included in each of the first portions AP1a and AP2a and the second portions AP1b and AP2b of the active patterns AP1 and AP2, channels of the memory transistor MT may be formed only in specific regions, thereby improving the operational characteristics of the memory transistor MT.

In embodiments, the length of each of the first portions AP1a and AP2a of each of the active patterns AP1 and AP2 in the third direction Z and the length of each of the second portions AP1b and AP2b in the third direction Z may be substantially the same. However, the present invention is not limited thereto, and the length of each of the first portions AP1a and AP2a of the active patterns AP1 and AP2 in the third direction Z, and the length of each of the second portions AP1b and AP2b in the third direction Z, may be variously changed.

Here, the length of each of the first portions AP1a and AP2a of the active patterns AP1 and AP2 in the third direction Z, and the length of each of the second portions AP1b and AP2b in the third direction Z may refer to the minimum distance in the third direction Z between one end portion in contact with the bit line BL and the other end portion in contact with the storage contact BC.

In embodiments, when a body voltage is applied to the first portions AP1a and AP2a of the active patterns AP1 and AP2, excess holes accumulated in the first portions AP1a and AP2a may be removed.

Here, “the body voltage” may be a negative voltage or a ground voltage, but is not limited thereto, and may vary depending on the type of the memory transistor MT.

Specifically, in embodiments, the end portions of the first portions AP1a and AP2a of the active patterns AP1 and AP2 may be positioned in the peripheral circuit region PAR and may be connected to a wiring configured to apply the body voltage to the first portions AP1a and AP2a. For example, as shown in FIG. 3, the end portions of the first portions AP1a and AP2a of the active patterns AP1 and AP2 in the peripheral circuit region PAR may be connected to cell connection wirings 232 configured to apply a body voltage through peripheral circuits PC positioned in the peripheral circuit structure PS.

Accordingly, as the body voltage (e.g., a negative voltage) applied from the peripheral circuit PC is applied to the first portions AP1a and AP2a of the active patterns AP1 and AP2 through the active pattern contact 241, excess holes accumulated in the first portions AP1a and AP2a may be discharged through the first portions AP1a and AP2a extending from the cell array region CAR to the peripheral circuit region PAR. In other words, the first portions AP1a and AP2a of the active patterns AP1 and AP2 may serve as a path for discharging excess holes. However, the method of applying a body voltage to the first portions AP1a and AP2a of the active patterns AP1 and AP2, and the connection relationship thereof, is not limited thereto and may be variously changed.

Unlike in FIG. 3, in some embodiments, the first portions AP1a and AP2a of the active patterns AP1 and AP2 may be connected to a wiring configured to apply the body voltage through a circuit positioned in the cell structure CS.

Further, in some embodiments, the first portions AP1a and AP2a of the active patterns AP1 and AP2 may be positioned in a peripheral circuit region PAR and may be connected to a wiring or a ground region configured to apply a ground voltage.

In embodiments, each of the first portions AP1a and AP2a of the active patterns AP1 and AP2 may have a first width W1, and each of the second portions AP1b and AP2b may have a second width W2.

Here, the first width W1 may refer to the maximum width of each of the first portions AP1a and AP2a of the active patterns AP1 and AP2 in the second direction Y, and the second width W2 may refer to the maximum width of each of the first portions AP1a and AP2a in the second direction Y.

In embodiments, the first width W1 may be different from the second width W2. For example, the first width W1 may be larger than the second width W2. However, the relationship between the first width W1 and the second width W2 is not limited thereto and may be variously changed.

As such, since the width each of the first portions AP1a and AP2a of the active patterns AP1 and AP2, which serve as paths for discharging excess holes, are greater than the width each of the second portions AP1b and AP2b, when a voltage is applied to the first portions AP1a and AP2a, the electrical resistance characteristics may be improved, and the discharge time of excess holes accumulated in the first portions AP1a and AP2a may be reduced.

According to embodiments of the semiconductor device, the active patterns AP1 and AP2 may include portions that constitute the source/drain electrodes and the channel regions of the memory transistor MT, and may further include additional portions to which a voltage is applied for removing or discharging excess holes generated and accumulated during the operation of the memory transistor MT, thereby preventing or suppressing the floating body effects.

Accordingly, by preventing variation in the threshold voltage of the memory transistor MT due to floating body effects, the operational characteristics and leakage current characteristics of the memory transistor MT may be improved, thereby providing a semiconductor device with enhanced reliability and productivity.

Hereinafter, semiconductor devices according to various embodiments will be described with reference to FIGS. 6 to 12. In the following embodiments, components identical to those in the above-described embodiment will be denoted by the same reference symbols, and a redundant description thereof will not be made or will be made in brief, and the differences in them from the above-described embodiment will be mainly described.

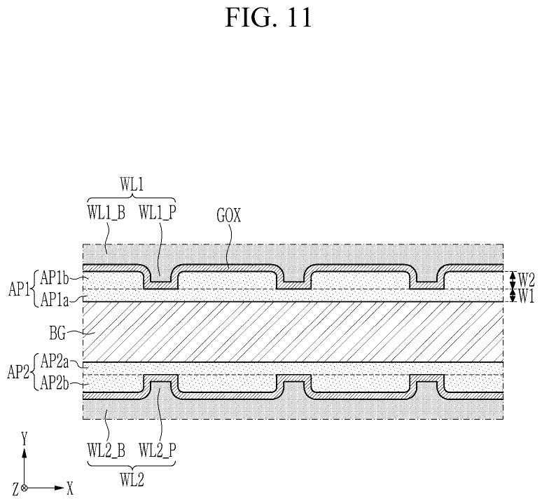

FIGS. 6 to 10 and 12 are cross-sectional views of a semiconductor device according to some embodiments. FIG. 11 is a plan view illustrating a part of a semiconductor device according to some embodiment.

Specifically, FIG. 6 to 10 and FIG. 12 are partial enlarged views illustrating regions P2 to P7 according to some embodiments which correspond to region P1 of FIG. 4.

According to semiconductor devices shown in FIGS. 6 to 8, unlike the semiconductor device of embodiments described above, each of the first portions AP1a and AP2a of the active patterns AP1 and AP2 is spaced apart from at least one of the bit line BL and the storage contact BC.

According to embodiments shown in FIG. 6, unlike the semiconductor device of embodiments described above, each of the first portions AP1a and AP2a of the active patterns AP1 and AP2 may be positioned spaced apart from the bit line BL.

Specifically, each of the first portions AP1a and AP2a of the active patterns AP1 and AP2 extends in a third direction Z between the bit line BL and the storage contact BC, and each of the first portions AP1a and AP2a may include a first surface AP_S1 and a second surface AP_S2 facing each other in the third direction Z.

Here, the first surface AP_S1 may refer to a surface adjacent to the bit line BL, and the second surface AP_S2 may refer to a surface adjacent to the storage contact BC. In other words, the first surface AP_S1 may refer to a lower surface of each of the first portions AP1a and AP2a of the active patterns AP1 and AP2, and the second surface AP_S2 may refer to an upper surface.

The semiconductor device according to the present embodiment may further include a first active capping pattern 133 positioned between first portions AP1a and AP2a of the active patterns AP1 and AP2 and the bit line BL.

The first active capping pattern 133 may be positioned between the first surface AP_S1 of each of the first portions AP1a and AP2a of the active patterns AP1 and AP2 and the bit line BL. The first active capping pattern 133 may extend in the third direction Z between the second portions AP1b and AP2b of the active patterns AP1 and AP2 and the separation insulating pattern 131.

Accordingly, the first surface AP_S1 of each of the first portions AP1a and AP2a of the active patterns AP1 and AP2 is spaced apart from the bit line BL, and the second surface AP_S2 may be in contact with the storage contact BC.

One end portion of the first active capping pattern 133 may be in contact with the bit line BL, and the other end portion may be in contact with the first portions AP1a and AP2a of the active patterns AP1 and AP2. However, it is not limited thereto, and another component may be further positioned at least one of between the first active capping pattern 133 and the bit line BL, and between the first active capping pattern 133 and the first portions AP1a and AP2a of the active patterns AP1 and AP2.

The first active capping pattern 133 may be positioned to overlap at least a portion of each of the second portions AP1b and AP2b of the active patterns AP1 and AP2 in a second direction Y that is parallel to the substrate 100.

One side surface of the first active capping pattern 133 may be in contact with the separation insulating pattern 131, and the other side surface may be in contact with the second portions AP1b and AP2b of the active patterns AP1 and AP2. However, it is not limited thereto, and another component may be further positioned between at least one of the first active capping pattern 133 and the second portions AP1b and AP2b of the active patterns AP1 and AP2, and between the first active capping pattern 133 and the separation insulating pattern 131.

The first portions AP1a and AP2a of each of the active patterns AP1 and AP2 and the bit line BL may be separated and insulated by the first active capping pattern 133.

The first active capping pattern 133 may contain an insulating material such as silicon oxide, silicon nitride, silicon oxynitride, and/or a low-k material. However, the material included in the first active capping pattern 133 is not limited thereto and may be variously changed.

In present embodiment, the first active capping pattern 133 is illustrated as having a single-layer structure, but is not limited thereto, and the first active capping pattern 133 may have a multi-layer structure including the same material and/or different materials.

In present embodiment, each of the second portions AP1b and AP2b of the active patterns AP1 and AP2 may have a first length H1 in the third direction Z, each of the first portions AP1a and AP2a may have a second length H2 in the third direction Z, and the first active capping pattern 133 may have a third length H3 in the third direction Z.

Here, the first length H1 may refer to the minimum length of each of the second portions AP1b and AP2b of the active patterns AP1 and AP2 in the third direction Z, the second length H2 may refer to the minimum length of each of the first portions AP1a and AP2a in the third direction Z, and the third length H3 may refer to the minimum length of the first active capping pattern 133 in the third direction Z.

In present embodiment, the first length H1 may be different from the second length H2. In other words, the length each of the first portions AP1a and AP2a and the second portions AP1b and AP2b of the active patterns AP1 and AP2 may be different. For example, the first length H1 may be longer than the second length H2 and the third length H3. In other words, the length of each of the second portions AP1b and AP2b of the active patterns AP1 and AP2 may be longer than the length each of the first portions AP1a and AP2a, and the length of each of the second portions AP1b and AP2b of the active patterns AP1 and AP2 may be longer than the length of the first active capping pattern 133.

In present embodiment, the sum of the second length H2 and the third length H3 may be substantially equal to the first length H1. In other words, the sum of the length of each of the first portions AP1a and AP2a of the active patterns AP1 and AP2 and the length of the first active capping pattern 133 may be substantially equal to the length of each of the second portions AP1b and AP2b of the active patterns AP1 and AP2.

Additionally, the second length H2 and the third length H3 may be different. In other words, the length of each of the first portions AP1a and AP2a of the active patterns AP1 and AP2 may be different from the length of the first active capping pattern 133. For example, the second length H2 may be longer than the third length H3. In other words, the length of each of the first portions AP1a and AP2a of the active patterns AP1 and AP2 may be longer than the length of the first active capping pattern 133. However, this is an example, and the relationship between the second length H2 and the third length H3 may be variously changed. For example, the second length H2 and the third length H3 may be substantially equal.

Accordingly, a portion of each of the second portions AP1b and AP2b of the active patterns AP1 and AP2 may overlap the first portions AP1a and AP2a in the second direction Y, which is a direction parallel to the substrate 100, and the remaining portion may overlap the first active capping pattern 133 in the second direction Y.

In present embodiment, the third length H3 may be longer than or equal to the length in the third direction Z of each of the first dopant regions SDR1_1 and SDR1_2 included in the second portions AP1b and AP2b of the active patterns AP1 and AP2.

For example, the second length H2 may be substantially equal to the sum of the length of each of the second dopant regions SDR2_1 and SDR2_2 included in the second portions AP1b and AP2b of the active patterns AP1 and AP2 in the third direction Z and the length of each of the channel regions CHR_1 and CHR_2 in the third direction Z, and the third length H3 may be substantially equal to the length of each of the first dopant regions SDR1_1 and SDR1_2 in the third direction Z.

As a more specific example, the second length H2 may be substantially equal to the sum of a length of the second dopant region SDR2_1 included in the second portion AP1b of the first active pattern AP1 in the third direction Z and a length of the channel region CHR_1 in the third direction Z.

Accordingly, each of the first dopant regions SDR1_1 and SDR1_2 of the second portions AP1b and AP2b of the active patterns AP1 and AP2 may overlap the first active capping pattern 133 in the second direction Y, and the channel regions CHR_1 and CHR_2 and the second dopant regions SDR2_1 and SDR2_2 may overlap each of the first portions AP1a and AP2a of the active patterns AP1 and AP2 in the second direction Y.

As another example, the second length H2 may be smaller than the sum of the length of each of the second dopant regions SDR2_1 and SDR2_2 included in the second portions AP1b and AP2b of the active patterns AP1 and AP2 in the third direction Z and the length of each of the channel regions CHR_1 and CHR_2 in the third direction Z, and the third length H3 may be longer than the length of each of the first dopant regions SDR1_1 and SDR1_2 in the third direction Z.

As a more specific example, the second length H2 may be smaller than the sum of the length of the second dopant region SDR2_1 included in the second portion AP1b of the first active pattern AP1 in the third direction Z and the length of the channel region CHR_1 in the third direction Z.

Accordingly, each of the first dopant regions SDR1_1 and SDR1_2 included in the second portions AP1b and AP2b of the active patterns AP1 and AP2 and a portion of each of the channel regions CHR_1 and CHR_2 may overlap the first active capping pattern 133 in the second direction Y, and the remaining portion of each of the channel regions CHR_1 and CHR_2 and each of the second dopant regions SDR2_1 and SDR2_2 may overlap the first portions AP1a and AP2a of the active patterns AP1 and AP2 in the second direction Y. However, the length relationship between the first active capping pattern 133 and each of the first dopant regions SDR1_1 and SDR1_2 of the active patterns AP1 and AP2 is not limited thereto and may be variously changed.

As described above, when the length of the first active capping pattern 133 in the third direction Z is substantially equal to or longer than the length of each of the first dopant regions SDR1_1 and SDR1_2 included in the second portions AP1b and AP2b in the third direction Z, diffusion of a dopant doped in the bit line BL or in the first dopant regions SDR1_1 and SDR1_2 into the first portions AP1a and AP2a of the active patterns AP1 and AP2 may be prevented.

According to the semiconductor device of the present embodiment, by forming the first portions AP1a and AP2a of the active patterns AP1 and AP2 to be spaced apart from the bit line BL, diffusion of a dopant included in the bit line BL or in the first dopant regions SDR1_1 and SDR1_2 into the first portions AP1a and AP2a may be prevented, thereby improving the operational characteristics and leakage current characteristics of the memory transistor MT.

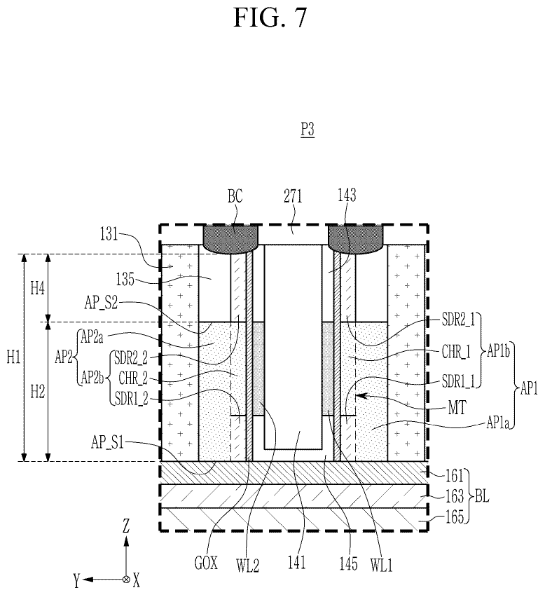

According to embodiments shown in FIG. 7, unlike the semiconductor device of embodiments described above, each of the first portions AP1a and AP2a of the active patterns AP1 and AP2 may be positioned spaced apart from the storage contact BC.

The semiconductor device according to the present embodiment may further include a second active capping pattern 135 positioned between first portions AP1a and AP2a of the active patterns AP1 and AP2 and the storage contact BC.

The second active capping pattern 135 may be positioned between the second surface AP_S2 of each of the first portions AP1a and AP2a of the active patterns AP1 and AP2 and the storage contact BC. The second active capping pattern 135 may extend in the third direction Z between the second portions AP1b and AP2b of the active patterns AP1 and AP2 and the separation insulating pattern 131.

Accordingly, the first surface AP_S1 of each of the first portions AP1a and AP2a of the active patterns AP1 and AP2 may be in contact with the bit line BL, and the second surface AP_S2 may be positioned apart from the storage contact BC.

One end portion of the second active capping pattern 135 may be in contact with the first portions AP1a and AP2a of the active patterns AP1 and AP2, and the other end portion may be in contact with the storage contact BC. However, it is not limited thereto, and another component may be further positioned at least one of between the second active capping pattern 135 and the first portions AP1a and AP2a of the active patterns AP1 and AP2, and between the second active capping pattern 135 and the storage contact BC.

The second active capping pattern 135 may be positioned to overlap at least a portion of each of the second portions AP1b and AP2b of the active patterns AP1 and AP2 in a second direction Y.

One side surface of the second active capping pattern 135 may be in contact with the separation insulating pattern 131, and the other side surface may be in contact with the second portions AP1b and AP2b of the active patterns AP1 and AP2. However, it is not limited thereto, and another component may be further positioned at least one between the second active capping pattern 135 and the second portions AP1b and AP2b of the active patterns AP1 and AP2, and between the second active capping pattern 135 and the separation insulating pattern 131.

The first portions AP1a and AP2a of the active patterns AP1 and AP2 and the storage contact BC may be separated and insulated by the second active capping pattern 135.

The second active capping pattern 135 may contain the same insulating material as the first active capping pattern 133 described above, but is not limited thereto. Further, in present embodiment, the second active capping pattern 135 is illustrated as having a single-layer structure, but is not limited thereto, and the second active capping pattern 135 may have a multi-layer structure including the same material and/or different materials.

In the present embodiment, each of the second portions AP1b and AP2b of the active patterns AP1 and AP2 may have a first length H1 in the third direction Z, each of the first portions AP1a and AP2a may have a second length H2 in the third direction Z, and the second active capping pattern 135 may have a fourth length H4 in the third direction Z.

Here, the first length H1 may refer to the minimum length of each of the second portions AP1b and AP2b of the active patterns AP1 and AP2 in the third direction Z, the second length H2 may refer to the minimum length of each of the first portions AP1a and AP2a in the third direction Z, and the fourth length H4 may refer to the minimum length of the second active capping pattern 135 in the third direction Z.

In the present embodiment, the relationship between the first length H1 and the second length H2, and the relationship between the sum of the second length H2 and the fourth length H4 and the first length H1, may be substantially the same as the relationship between the first length H1 and the second length H2, and the relationship between the sum of the second length H2 and the third length H3 and the first length H1, as described above with reference to FIG. 6. Accordingly, a detailed description thereof will be omitted, and the following description will emphasis on the differences from embodiments shown in FIG. 6.

In present embodiment, the second length H2 and the fourth length H4 may be different. In other words, the length of each of the first portions AP1a and AP2a of the active patterns AP1 and AP2 may be different from the length of the second active capping pattern 135. For example, the second length H2 may be longer than the fourth length H4. In other words, the length of each of the first portions AP1a and AP2a of the active patterns AP1 and AP2 may be longer than the length of the second active capping pattern 135. However, this is an example, and the relationship between the second length H2 and the fourth length H4 may be variously changed. For example, the second length H2 and the fourth length H4 may be substantially equal.

Accordingly, a portion of each of the second portions AP1b and AP2b of the active patterns AP1 and AP2 may overlap the first portions AP1a and AP2a in the second direction Y, and the remaining portion may overlap the second active capping pattern 135 in the second direction Y.

In the present embodiment, the fourth length H4 may be equal to or longer than the length in the third direction Z of each of the second dopant regions SDR2_1 and SDR2_2 included in the second portions AP1b and AP2b of the active patterns AP1 and AP2.

For example, the second length H2 may be substantially equal to the sum of the length of each of the first dopant regions SDR1_1 and SDR1_2 included in the second portions AP1b and AP2b of the active patterns AP1 and AP2 in the third direction Z and the length of each of the channel regions CHR_1 and CHR_2 in the third direction Z, and the fourth length H4 may be substantially equal to the length of each of the second dopant regions SDR2_1 and SDR2_2 in the third direction Z.

As a more specific example, the second length H2 may be substantially equal to the sum of the length of the first dopant region SDR1_1 included in the second portion AP1b of the first active pattern AP1 in the third direction Z, and the length of the channel region CHR_1 in the third direction Z.

Accordingly, the first dopant regions SDR1_1 and SDR1_2 and the channel regions CHR_1 and CHR_2 included in the second portions AP1b and AP2b of the active patterns AP1 and AP2 may overlap the first portions AP1a and AP2a of the active patterns AP1 and AP2 in the second direction Y, and the second dopant regions SDR2_1 and SDR2_2 may overlap the second active capping pattern 135 in the second direction Y.

As another example, the second length H2 may be smaller than the sum of the length of each of the first dopant regions SDR1_1 and SDR1_2 included in the second portions AP1b and AP2b of the active patterns AP1 and AP2 in the third direction Z and the length of each of the channel regions CHR_1 and CHR_2 in the third direction Z, and the fourth length H4 may be longer than the length of each of the second dopant regions SDR2_1 and SDR2_2 in the third direction Z.

As a more specific example, the second length H2 may be smaller than the sum of the length of the first dopant region SDR1_1 included in the second portion AP1b of the first active pattern AP1 in the third direction Z and the length of the channel region CHR_1 in the third direction Z.

Accordingly, each of the first dopant regions SDR1_1 and SDR1_2 and each of the channel regions CHR_1 and CHR_2 included in the second portions AP1b and AP2b of the active patterns AP1 and AP2 may overlap the first portions AP1a and AP2a of the active patterns AP1 and AP2 in the second direction Y, and the remaining portion of each of the channel regions CHR_1 and CHR_2 and each of the second dopant regions SDR2_1 and SDR2_2 may overlap the second active capping pattern 135 in the second direction Y. However, the length relationship between the second active capping pattern 135 and each of the second dopant regions (SDR2_1, SDR2_2) of the active patterns (AP1, AP2) is not limited thereto and may be changed in various ways.

As described above, when the length of the second active capping pattern 135 in the third direction Z is substantially the same as the length of each of the second dopant regions SDR2_1 and SDR2_2 included in the second portions AP1b and AP2b of the active patterns AP1 and AP2 in the third direction Z, or is longer than the length of each of the second dopant regions SDR2_1 and SDR2_2 in the third direction Z, the dopant doped in the storage contact BC or the dopant doped in the second dopant regions SDR2_1 and SDR2_2 may be prevented from diffusing into the first portions AP1a and AP2a of the active patterns AP1 and AP2.

According to the semiconductor device according to the present embodiment, may have substantially the same effect as the semiconductor device according to embodiments shown in FIG. 6.

Specifically, by forming the first portions AP1a and AP2a of the active patterns AP1 and AP2 to be spaced apart from the storage contact BC, the dopant doped in the storage contact BC or the dopant doped in the second dopant regions SDR2_1 and SDR2_2 is prevented from diffusing into the first portions AP1a and AP2a of the active patterns AP1 and AP2, thereby improving the operating characteristics and leakage current characteristics of the memory transistor MT.

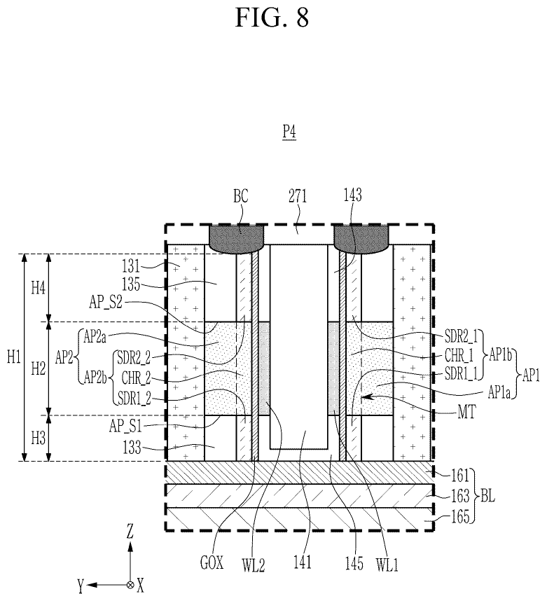

According to embodiments shown in FIG. 8, unlike the semiconductor device according to the above embodiment, each of the first portions AP1a and AP2a of the active patterns AP1 and AP2 may be positioned spaced apart from the storage contact BC and the bit line BL.

The semiconductor device according to the present embodiment may further include the first active capping pattern 133 positioned between first portions AP1a and AP2a of the active patterns AP1 and AP2 and the bit line BL, and the second active capping pattern 135 positioned between first portions AP1a and AP2a of the active patterns AP1 and AP2 and a storage contact BC.

Accordingly, the first surface AP_S1 of each of the first portions AP1a and AP2a of the active patterns AP1 and AP2 may be positioned spaced apart from the bit line BL, and the second surface AP_S2 may be positioned spaced apart from the storage contact BC.

In this embodiment, the first active capping pattern 133 is substantially the same as the first active capping pattern 133 according to embodiments shown in FIG. 6, and the second active capping pattern 135 is substantially the same as the second active capping pattern 135 according to embodiments shown in FIG. 7, and thus a detailed description thereof will not be made.

In the present embodiment, each of the second portions AP1b and AP2b of the active patterns AP1 and AP2 may have a first length H1 in the third direction Z, each of the first portions AP1a and AP2a may have a second length H2 in the third direction Z, the first active capping pattern 133 may have a third length H3 in the third direction Z, and the second active capping pattern 135 may have a fourth length H4 in the third direction Z.

In present embodiment, the relationship between the first length H1 and the second length H2 may be substantially equally applied to the relationship between the first length H1 and the second length H2 described above with reference to FIG. 6, and thus a detailed description thereof will not be made.

In present embodiment, the sum of the second length H2, the third length H3, and the fourth length H4 may be substantially equal to the first length H1. That is, the sum of the lengths of the first portions AP1a and AP2a of each of the active patterns AP1 and AP2, the length of the first active capping pattern 133, and the second active capping pattern 135 may be substantially equal to the length of the second portions AP1b and AP2b of each of the active patterns AP1 and AP2.

Further, at least one of the second length H2, the third length H3, and the fourth length H4 may be different. That is, at least one of the lengths of each of the first portions AP1a and AP2a of the active patterns AP1 and AP2, the length of the first active capping pattern 133, and the length of the second active capping pattern 135 may be different.

Accordingly, the second portions AP1b and AP2b of the active patterns AP1 and AP2 may overlap the first active capping pattern 133, the first portions AP1a and AP2a of the active patterns AP1 and AP2, and the second active capping pattern 135 in the second direction Y.

In present embodiment, the second length H2, the third length H3, and the fourth length H4 may be different. For example, the second length H2 may be longer than the third length H3 and the fourth length H4, and the fourth length H4 may be longer than the third length H3. That is, the length of each of the first portions AP1a and AP2a of the active patterns AP1 and AP2 may be longer than each of the lengths of the first active capping pattern 133 and the length of the second active capping pattern 135, and the length of the second active capping pattern 135 may be longer than the length of the first active capping pattern 133.

As a more specific example, the second length H2 may be substantially equal to the length in the third direction Z of each of the channel regions CHR_1 and CHR_2 included in the second portions AP1b and AP2b of the active patterns AP1 and AP2, the third length H3 may be substantially equal to the length in the third direction Z of each of the first dopant regions SDR1_1 and SDR1_2 included in the second portions AP1b and AP2b of the active patterns AP1 and AP2, and the fourth length H4 may be substantially equal to the length in the third direction Z of each of the second dopant regions SDR2_1 and SDR2_2 included in the second portions AP1b and AP2b of the active patterns AP1 and AP2.

Accordingly, each of the first dopant regions SDR1_1 and SDR1_2 included in the second portions AP1b and AP2b of the active patterns AP1 and AP2 overlaps the first active capping pattern 133 in the second direction Y, each of the channel regions CHR_1 and CHR_2 overlaps the first portions AP1a and AP2a of the active patterns AP1 and AP2 in the second direction Y, and each of the second dopant regions SDR2_1 and SDR2_2 may overlap the second active capping pattern 135 in the second direction Y.

As another example, the second length H2 may be shorter than the length in the third direction Z of each of the channel regions CHR_1 and CHR_2 included in the second portions AP1b and AP2b of the active patterns AP1 and AP2, the third length H3 may be longer than the length in the third direction Z of each of the first dopant regions SDR1_1 and SDR1_2 included in the second portions AP1b and AP2b of the active patterns AP1 and AP2, and the fourth length H4 may be substantially equal to the length in the third direction Z of each of the second dopant regions SDR2_1 and SDR2_2 included in the second portions AP1b and AP2b of the active patterns AP1 and AP2.

Accordingly, each of the first dopant regions SDR1_1 and SDR1_2 and a portion of each of the channel regions CHR_1 and CHR_2 may overlap the first active capping pattern 133 in the second direction Y, while the remaining portion of each of the channel regions CHR_1 and CHR_2 may overlap the first portions AP1a and AP2a of the active patterns in the second direction Y, and each of the second dopant regions SDR2_1 and SDR2_2 may overlap the second active capping pattern 135 in the second direction Y.

As another example, the second length H2 may be shorter than the length in the third direction Z of each of the channel regions CHR_1 and CHR_2 included in the second portions AP1b and AP2b of the active patterns AP1 and AP2, the third length H3 may be substantially equal to the length in the third direction Z of each of the first dopant regions SDR1_1 and SDR1_2 included in the second portions AP1b and AP2b of the active patterns AP1 and AP2, and the fourth length H4 may be longer than the length in the third direction Z of each of the second dopant regions SDR2_1 and SDR2_2 included in the second portions AP1b and AP2b of the active patterns AP1 and AP2.

Accordingly, each of the first dopant regions SDR1_1 and SDR1_2 included in the second portions AP1b and AP2b of the active patterns AP1 and AP2 overlaps the first active capping pattern 133 in the second direction Y, a portion of each of the channel regions CHR_1 and CHR_2 overlaps the first portions AP1a and AP2a of the active patterns AP1 and AP2 in the second direction Y, while the remaining portion of each of the channel regions CHR_1 and CHR_2 and each of the second dopant regions SDR2_1 and SDR2_2 may overlap the second active capping pattern 135 in the second direction Y. However, this is not limited, and the relationship between the second length H2, the third length H3, and the fourth length H4 may be variously changed depending on the length in the third direction Z of each of the first dopant regions SDR1_1 and SDR1_2, the second dopant regions SDR2_1 and SDR2_2, and the channel regions CHR_1 and CHR_2 included in the second portions AP1b and AP2b of the active patterns AP1 and AP2.

As described above, when the length of the first active capping pattern 133 in the third direction Z is longer than or substantially equal to the length of each of the first dopant regions SDR1_1 and SDR1_2 included in the second portions AP1b and AP2b of the active patterns AP1 and AP2 in the third direction Z, and the length of the second active capping pattern 135 in the third direction Z is longer than or substantially equal to the length of each of the second dopant regions SDR2_1 and SDR2_2 included in the second portions AP1b and AP2b of the active patterns AP1 and AP2 in the third direction Z, it is possible to prevent dopants doped in the bit line BL, the storage contact BC, and the first and second dopant regions SDR1_1, SDR1_2, SDR2_1, and SDR2_2 from diffusing into the first portions AP1a and AP2a of the active patterns AP1 and AP2.

According to the semiconductor device according to the present embodiment, may have substantially the same effect as the semiconductor device according to embodiments shown in FIG. 6 and FIG. 7.

Specifically, by forming the first portions AP1a and AP2a of the active patterns AP1 and AP2 to be spaced apart from the bit line BL and the storage contact BC, the dopant doped in the bit line BL, the dopant doped in the storage contact BC, and the dopant doped in the first and second dopant regions SDR1_1, SDR1_2, SDR2_1 and SDR2_2 are prevented from diffusing into the first portions AP1a and AP2a of the active patterns AP1 and AP2, thereby improving the operating characteristics and leakage current characteristics of the memory transistor MT.

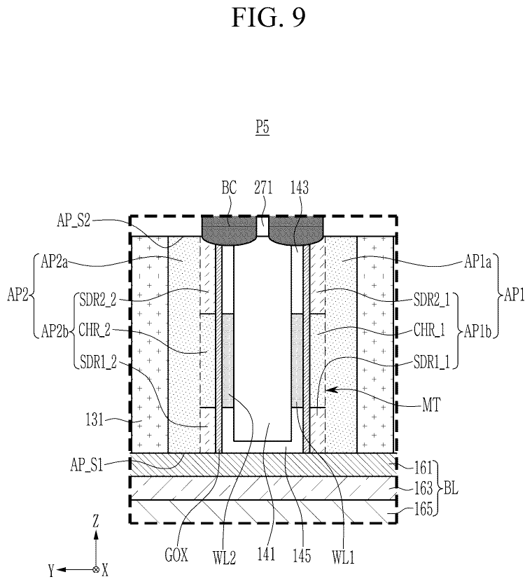

According to embodiments shown in FIG. 9, unlike the semiconductor device according to above embodiments, there is a difference in that the arrangement between the storage contact BC and the first portions AP1a and AP2a of the active patterns AP1 and AP2 is different.

Referring to FIG. 9, the storage contact BC may be positioned so as to non-overlap each of the first portions AP1a and AP2a of the active patterns AP1 and AP2 in the third direction Z and overlap each of the second portions AP1b and AP2b in the third direction Z. That is, the storage contact BC may be positioned so as to be spaced apart from each of the first portions AP1a and AP2a of the active patterns AP1 and AP2, and the storage contact BC may be positioned so as to be in contact only with the second portions AP1b and AP2b of the active patterns AP1 and AP2.

In present embodiment, the storage contact BC may be positioned to entirely overlap each of the word lines WL1 and WL2. That is, each of the word lines WL1 and WL2 may entirely overlap the storage contact BC in the third direction Z.

According to the present embodiment, unlike embodiments shown in FIG. 5, the first portions AP1a and AP2a of the active patterns AP1 and AP2 may not be recessed by the storage contact BC, and thus, one surface of each of the first portions AP1a and AP2a adjacent to the storage contact BC may have a straight shape.

Specifically, one surface of each of the first portions AP1a and AP2a of the active patterns AP1 and AP2 adjacent to the storage contact BC may be positioned at substantially the same level as the upper surface of the separation insulating pattern 131. That is, one surface of each of the first portions AP1a and AP2a of the active patterns AP1 and AP2 adjacent to the storage contact BC and the upper surface of the separation insulating pattern 131 may be substantially flat.

In the present embodiment, the first portions AP1a and AP2a of the active patterns AP1 and AP2 do not overlap the storage contact BC, and the second portions AP1b and AP2b are recessed by the storage contact BC, so that one surface of each of the first portions AP1a and AP2a of the active patterns AP1 and AP2 adjacent to the storage contact BC may be positioned at a higher level than one surface of each of the second portions AP1b and AP2b of the active patterns AP1 and AP2 adjacent to the storage contact BC.

Accordingly, the length of the first portions AP1a and AP2a of the active patterns AP1 and AP2 in the third direction Z may be longer than the length of the second portions AP1b and AP2b in the third direction Z.

Here, the length of each of the first portions AP1a and AP2a of the active patterns AP1 and AP2 in the third direction Z and the length of each of the second portions AP1b and AP2b in the third direction Z may refer to a minimum length in the third direction Z.

According to the semiconductor device according to the present embodiment, may have substantially the same effect as the semiconductor device according to embodiments shown in FIG. 7.

Specifically, by forming the storage contact BC so as to be spaced apart from the first portions AP1a and AP2a of the active patterns AP1 and AP2, the dopant doped in the storage contact BC or the dopant doped in each of the second dopant regions SDR2_1 and SDR2_2 is prevented from diffusing into the first portions AP1a and AP2a of the active patterns AP1 and AP2, thereby improving the operating characteristics and leakage current characteristics of the memory transistor MT.

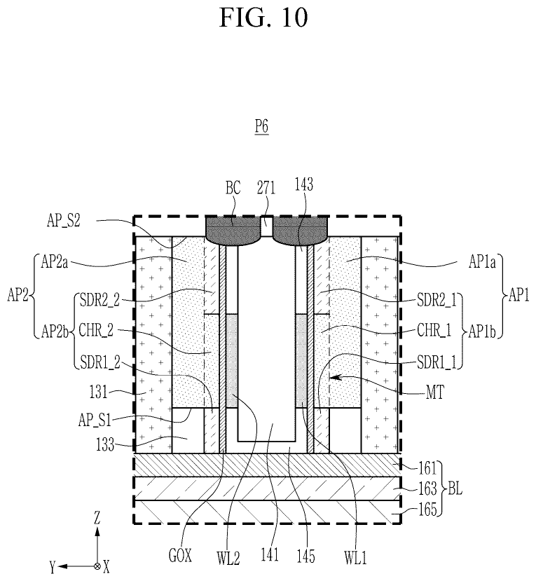

According to embodiments shwon in FIG. 10, unlike embodiments shown in FIG. 9, there is a difference in that a first active capping pattern 133 is further included between each of the first portions AP1a and AP2a of the active patterns AP1 and AP2 and the bit line BL.

In the present embodiment, the first active capping pattern 133 is substantially the same as the first active capping pattern 133 according to embodiments shown in FIG. 6. A description of the relationship between the length of the first active capping pattern 133 in the third direction Z and the lengths of the second portions AP1b and AP2b of the active patterns AP1 and AP2 in the third direction Z may be applied in substantially the same manner as described, and thus a detailed description thereof will not be made.

According to the present embodiment, unlike the semiconductor device according to embodiments shown in FIG. 9, the first active capping pattern 133 may be positioned between the first surface AP_S1 of each of the first portions AP1a and AP2a of the active patterns AP1 and AP2 and the bit line BL.

Accordingly, the first portions AP1a and AP2a of each of the active patterns AP1 and AP2 may be positioned spaced apart from the bit line BL by the first active capping pattern 133, and the second surfaces AP_S2 of each of the first portions AP1a and AP2a of the active patterns AP1 and AP2 may be positioned spaced apart from the storage contact BC.

In present embodiment, the first surface AP_S1 of each of the first portions AP1a and AP2a of the active patterns AP1 and AP2 may be in contact with the first active capping pattern 133, and the second surface AP_S2 may be in contact with the interlayer insulating layer 271 that separates and insulates adjacent storage contacts BC. However, it is not limited thereto, and other components may be further positioned between the first surface AP_S1 of each of the first portions AP1a and AP2a of the active patterns AP1 and AP2 and the first active capping pattern 133, and between the second surface AP_S2 of each of the first portions AP1a and AP2a of the active patterns AP1 and AP2 and the contact interlayer insulating layer 271.

Although not shown, unlike embodiments shown in FIG. 10, the semiconductor device according to some embodiments may further include a second active capping pattern (not shown in the drawings) positioned between each of the first portions AP1a and AP2a of the active patterns AP1 and AP2 and the contact interlayer insulating layer 271.

The second active capping pattern may be positioned between the second surface AP_S2 of each of the first portions AP1a and AP2a of the active patterns AP1 and AP2 and contact interlayer insulating layer 271.

Accordingly, the first surface AP_S1 of each of the first portions AP1a and AP2a of the active patterns AP1 and AP2 may be in contact with the first active capping pattern 133, and the second surface AP_S2 may be in contact with the second active capping pattern (not shown in the drawings).

Here, the second active capping pattern is substantially equal to the second active capping pattern 135 included in the semiconductor device according to embodiments shown in FIG. 8, and the description of the second active capping pattern 135 described above with reference to FIG. 8 may be substantially equally applied to the second active capping pattern included in the semiconductor device according to the present embodiment.

According to the semiconductor device according to the present embodiment, may have substantially the same effect as the semiconductor device according to embodiments shown in FIG. 8.

Specifically, since one end portion of the first portions AP1a and AP2a of the active patterns AP1 and AP2 is positioned so as to not overlap the storage contact BC and the other end portion is formed so as to be spaced apart from the bit line BL, the dopant doped in the storage contact BC and the dopant doped in each of the second dopant regions SDR2_1 and SDR2_2 are prevented from diffusing into the first portions AP1a and AP2a of the active patterns AP1 and AP2, thereby improving the operating characteristics and leakage current characteristics of the memory transistor MT.

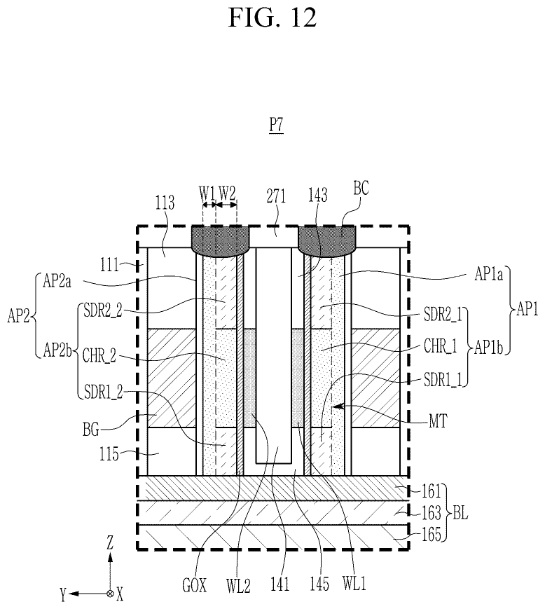

According to embodiments shown in FIG. 11 and FIG. 12, unlike the semiconductor device of embodiments described above, the separation insulating pattern (‘131’ in FIG. 2 and FIG. 5) positioned between adjacent active patterns AP1 and AP2 is omitted, and a back gate electrode BG positioned between adjacent active patterns AP1 and AP2 is further included.

Further, unlike the semiconductor device according to embodiments described above, the present embodiment further includes a back gate electrode BG, and the relationship between the widths of the first portions AP1a and AP2a and the second portions AP1b and AP2b of the active patterns differs.

Referring to FIGS. 11 and 12, the semiconductor device according to the present embodiment may further include a back gate electrode BG extending in a different direction from the bit line BL between the first active pattern AP1 and the second active pattern AP2.

The back gate electrode BG may be positioned between the first word line WL1 and the second word line WL2 which are adjacent in the second direction Y. For example, the first active pattern AP1 may be positioned between the first word line WL1 and the back gate electrode BG, and the second active pattern AP2 may be positioned between the second word line WL2 and the back gate electrode BG. However, this is an example, and the arrangement of the active patterns AP1 and AP2, the second word lines WL1 and WL2, and the back gate electrode BG is not limited thereto and may be variously changed.

In present embodiment, the back gate electrode BG may be positioned between adjacent active patterns (AP1 and AP2) in the second direction Y. For example, the back gate electrode BG may extend in the first direction X between the first portion AP1a of the first active pattern AP1 and the first portion AP2a of the second active pattern AP2.

As shown FIG. 11 and FIG. 12, one back gate electrode BG is illustrated, but this is not limited thereto, and the semiconductor device according to the present embodiment may include a plurality of back gate electrodes BG extending in the first direction X between each of the active patterns AP1 and AP2 spaced apart in the second direction Y.

In the present embodiment, the length of the back gate electrode BG in the third direction Z may be smaller than the length of each of the active patterns AP1 and AP2 in the third direction Z.

Further, the length of the back gate electrode BG in the third direction Z may be substantially equal to the length of each of the word lines WL1 and WL2 in the third direction Z. However, this is an example, and the length relationship in the third direction Z of each of the active patterns AP1 and AP2, the back gate electrode BG, and the word lines WL1, WL2 may be variously changed. For example, the length of the back gate electrode BG in the third direction Z may be different from the length of each of the word lines WL1 and WL2 in the third direction Z.

The back gate electrode BG may include first and second surfaces facing each other in the third direction Z.

Here, the first surface of the back gate electrode BG may refer a surface adjacent to the bit line BL, and the second surface of the back gate electrode BG may refer to a surface adjacent to the storage contact BC. That is, the first surface of the back gate electrode BG may refer to the lower surface of the back gate electrode BG, and the second surface may refer to the upper surface of the back gate electrode BG.

In the present embodiment, the first surface of the back gate electrode BG may be positioned at substantially the same level as the first surface of each of the word lines WL1 and WL2, and the second surface of the back gate electrode BG may be positioned at substantially the same level as the second surface of each of the word lines WL1 and WL2. That is, the back gate electrode BG may be positioned to overlap each of the word lines WL1 and WL2 and the entirety in the second direction Y.

Further, the back gate electrode BG and each of the word lines WL1 and WL2 may be positioned at substantially the same level and may be positioned to correspond to each of the channel regions CHR_1 and CHR_2 of the active patterns AP1 and AP2.

In present embodiment, the width of the back gate electrode BG in the second direction Y may be different from the width of each of the word lines WL1 and WL2 in the second direction Y. For example, the width of the back gate electrode BG may be greater than the width of each of the word lines WL1 and WL2. However, this is an example, and the relationship between the width of the back gate electrode BG in the second direction Y and the width of each of the word lines WL1 and WL2 in the second direction Y may be variously changed. For example, the width of the back gate electrode BG in the second direction Y may be smaller than or substantially equal to the width of each of the word lines WL1 and WL2 in the second direction Y.

The back gate electrode BG may contain a conductive material. For example, the back gate electrode BG may contain at least one of doped polysilicon, conductive metal nitrides, conductive metal silicon nitrides, metal carbon nitrides, conductive metal silicides, conductive metal oxides, two-dimensional materials, and metals. However, this is an example, and the conductive material may be variously changed.

The semiconductor device according to the present embodiment may further include a back gate insulating pattern 111, a first back gate capping pattern 113, and a second back gate insulating pattern 115.

The back gate insulating pattern 111 may be positioned on both side surfaces of the back gate electrode BG.

The back gate insulating pattern 111 may conformally extend in the third direction Z between the back gate electrode BG and the active patterns AP1 and AP2. One side surface of the back gate insulating pattern 111 may be in contact with the back gate electrode BG, and the other side surface may be in contact with the first portions AP1a and AP2a of each of the active patterns AP1 and AP2.

The first back gate capping pattern 113 extends in the third direction Z on the second surface of the back gate electrode BG, and both side surfaces of the first back gate capping pattern 113 may be surrounded by the back gate insulating pattern 111. That is, the first back gate capping pattern 113 may be positioned between the back gate electrode BG and the contact interlayer insulating layer 271.

Further, the second back gate capping pattern 115 extends in the third direction Z on the first surface of the back gate electrode BG, and both side surfaces of the second back gate capping pattern 115 may be surrounded by the back gate insulating pattern 111. That is, the second back gate capping pattern 115 may be positioned between the bit line BL and the back gate electrode BG.

The back gate insulating pattern 111, the first back gate capping pattern 113, and the second back gate capping pattern 115 may each contain an insulating material. For example, the back gate insulating pattern 111, the first back gate capping pattern 113, and the second back gate capping pattern 115 may contain any one of silicon oxide, silicon oxynitride, silicon nitride, or a combination thereof. However, the back gate insulating pattern 111, the first back gate capping pattern 113, and the second back gate capping pattern 115 are not limited to these materials and may be variously changed.

In present embodiment, each of the first portions AP1a and AP2a of the active patterns AP1 and AP2 may have a first width W1, and each of the second portions AP1b and AP2b may have a second width W2.

Here, each of the first width W1 and the second width W2 may refer to a maximum width in the second direction Y.

In present embodiment, the first width W1 may be different from the second width W2. For example, the first width W1 may be smaller than the second width W2. That is, each of the first portions AP1a and AP2a of the active patterns AP1 and AP2 may be smaller than the width of each of the second portions AP1b and AP2b.

This may be a result of omitting the separation insulating pattern (see ‘131’ of FIG. 2 and FIG. 5) positioned between adjacent active patterns AP1 and AP2, unlike the semiconductor device according to the above embodiment, and further including the back gate electrode BG and insulating patterns surrounding it.

In the present embodiment, even when the width of each of the first portions AP1a and AP2a of the active patterns AP1 and AP2 that serve as passages for emitting excess holes is relatively reduced compared to the semiconductor device according to the above embodiment, excess holes accumulated in the first portions AP1a and AP2a of the active patterns AP1 and AP2 may be effectively removed by applying voltage to the back gate electrode BG.

Unlike as shown in FIG. 11 and FIG. 12, in some embodiments, the relationship between the first width W1 and the second width W2 may be variously changed. That is, the relationship between the first width W1 and the second width W2 may be changed in various ways as the width of the back gate electrode BG is varied. For example, the first width W1 may be greater than or substantially equal to the second width W2. That is, the width of each of the first portions AP1a and AP2a of the active patterns AP1 and AP2 may be greater than or substantially equal to the width of each of the second portions AP1b and AP2b.

In addition, unlike as shown in FIG. 11 and FIG. 12, the semiconductor device according to the present embodiment may further include at least one of the first active capping pattern (see ‘133’ of FIG. 8) positioned between the first portions AP1a and AP2a of the active patterns AP1 and AP2 and the bit line BL, and the second active capping pattern (see ‘135’ of FIG. 8) positioned between the first portions AP1a and AP2a of the active patterns AP1 and AP2 and the storage contact BC, substantially the same as in embodiments shown in FIGS. 6 to 10, or the storage contact BC may be positioned so as not to overlap each of the first portions AP1a and AP2a of the active patterns AP1 and AP2.

According to the semiconductor device according to the present embodiment, a negative voltage may be applied to a back gate electrode BG during operation of the semiconductor device, and a threshold voltage of a memory transistor MT including a vertical channel may be increased. That is, it is possible to prevent leakage current characteristics from deteriorating due to a decrease in threshold voltage caused by miniaturization of memory transistors MT.

Futher, according to the semiconductor device according to the present embodiment, by further including a back gate electrode BG, the floating body effect may be prevented or suppressed more effectively.

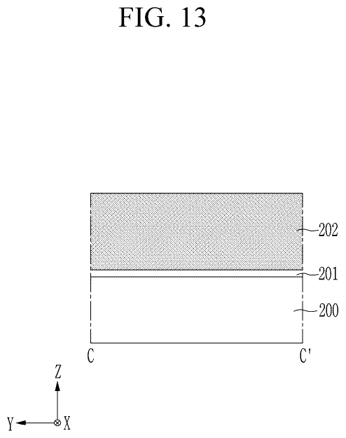

Hereinafter, a method of manufacturing the semiconductor device will be described with reference to FIGS. 13 to 22. Hereinafter, components identical to components described above will be denoted by the same reference symbols, and a redundant description thereof will not be made or will be made in brief, and the differences in them from the above-described components will be mainly described.

FIGS. 13 to 22 are views for explaining the method of manufacturing the semiconductor device according to embodiments.

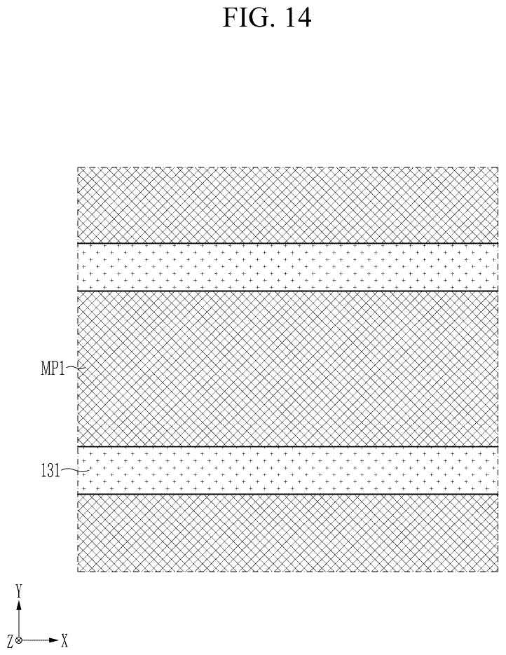

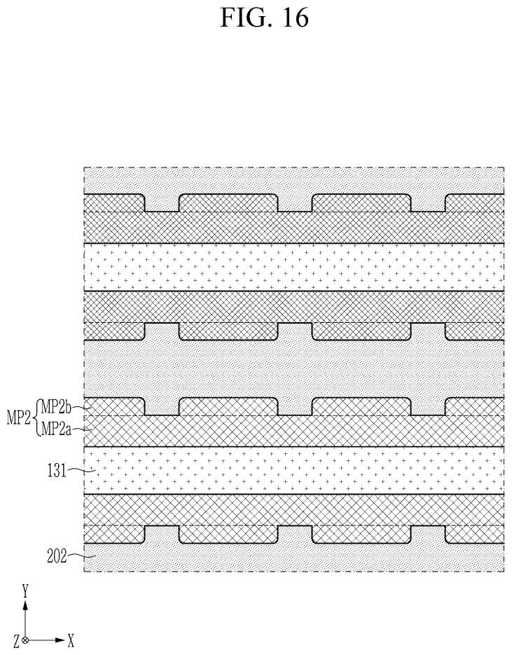

Specifically, FIGS. 13, 15, and 17 to 22 are cross-sectional views taken along the line C-C′ of FIG. 1 in individual manufacturing process steps for explaining the method of manufacturing the semiconductor device according to embodiments, and FIGS. 14 and 16 are plan views showing regions corresponding to the cell array region CAR for explaining the method of manufacturing the semiconductor device according to embodiments.

First, referring to FIG. 13, a buried insulating layer 201 and an active layer 202 may be formed on a sub substrate 200. The sub substrate 200, the buried insulating layer 201, and the active layer 202 may be a silicon-on-insulator substrate (SOI substrate).

The buried insulating layer 201 may be, for example, buried oxide (BOX) formed by a separation by implanted oxygen (SIMOX) method or a bonding and layer transfer method. As another example, the buried insulating layer 201 may be an insulating layer formed by a chemical vapor deposition method.

The buried insulating layer 201 may contain, for example, silicon oxide, silicon nitride, silicon oxynitride, and/or a low-dielectric constant material.

The active layer 202 may be a monocrystalline semiconductor layer. The active layer 202 may be, for example, a monocrystalline silicon substrate, a germanium substrate, and/or a silicon-germanium substrate.

The active layer 202 may include a first dopant. For example, the first dopant may be a p-type dopant such as aluminum (Al), boron (B), indium (In), gallium (Ga), or a combination thereof. However, the dopant included in the active layer 202 is not limited thereto, and may be variously changed.

In embodiments, the active layer 202 may be formed using a single crystal semiconductor material doped with the first dopant. However, it not limited thereto. In some embodiments, after forming the active layer 202 using the single crystal semiconductor material, a process of doping the active layer 202 with the first dopant described above by performing a gas phase doping GPD process or a plasma doping PLAD process may be further included.

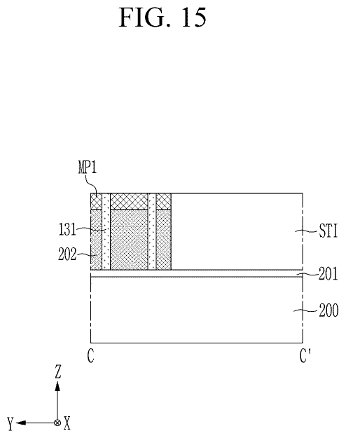

Subsequently, referring to FIG. 14 and FIG. 15, inside the active layer 202, the element isolation layer STI may be formed.

The element isolation layer STI may be formed by forming an element isolation trench so as to expose the buried insulating layer 201 by patterning the active layer 202, and then filling an insulating material in the element isolation trench.

The element isolation layer STI may be formed in a region corresponding to the peripheral circuit region (see ‘PAR’ of FIG. 4). As the element isolation layer STI is formed, the cell array region (see ‘CAR’of FIG. 3) may be defined.

Subsequently, a first mask pattern MP1 may be formed on the active layer 202.

Specifically, the first mask pattern MP1 may be formed on the active layer 202.

That is, the first mask pattern MP1 may be formed to remain on the active layer 202 corresponding to the cell array region (see ‘CAR’ of FIG. 4) in the process of patterning the active layer 202 to form the element isolation layer STI. The first mask pattern MP1 may expose at least a portion of the active layer 202.

The first mask pattern MP1 may contain an insulating material. For example, the first mask pattern MP1 may contain at least one of silicon oxide, silicon oxynitride, silicon nitride, silicon carbide (SiC), and silicon carbon nitride (SiCN), but is not limited thereto.

In embodiments, the first mask pattern MP1 is illustrated as having a single-layer structure, but is not limited thereto. For example, in some embodiments, the first mask pattern MP1 may have a multilayer structure including materials having different etch selectivities.

Subsequently, the active layer 202 may be patterned to form a plurality of separation insulating patterns 131.

Specifically, the process of forming the separation insulating pattern 131 may include a process of forming a trench by removing a portion of the active layer 202 using the first mask pattern MP1 as an etching mask to expose the buried insulating layer 201, and then filling an insulating material for forming the separation insulating pattern 131 in the trench, and a process of performing a planarization process on the separation insulating pattern 131 formed on the first mask pattern MP1 and the element isolation layer STI.

Accordingly, the upper surface of the first mask pattern MP1, the upper surface of the separation insulating pattern 131, and the upper surface of the element isolation layer STI are positioned at substantially the same level and may be substantially flat.

A plurality of separation insulating patterns 131 may extend in the third direction Z through the active layer 202. The plurality of separation insulating patterns 131 may be arranged to extend in a first direction X on a plane and be spaced apart in a second direction Y. That is, the plurality of separation insulating patterns 131 may have a line shape on a plane.

The separation insulating pattern 131 may contain an insulating material. For example, the separation insulating pattern 131 may contain any one of silicon oxide, silicon nitride, or a combination thereof. However, it is not limited to thereto, and the material of the separation insulating pattern 131 may be variously changed.

Subsequently, referring further to FIGS. 2, 16, and 17 with FIGS. 14 and 15, a second mask pattern MP2 may be formed on the active layer 202.

In embodiments, the second mask pattern MP2 may be formed by patterning the first mask pattern MP1 used as an etching mask in the process of patterning the active layer 202 to form the separation insulating pattern 131. That is, the second mask pattern MP2 may contain the same material as the first mask pattern MP1. However, it is not limited to thereto.

In some embodiments, after removing the first mask pattern MP1, the second mask pattern MP2 may be separately formed on the active layer 202.

In this case, the second mask pattern MP2 may contain a different material from the first mask pattern MP1, but is not limited thereto, and the second mask pattern MP2 may contain the same material as the first mask pattern MP1.

In embodiments, the second mask pattern MP2 is illustrated as having a single-layer structure, but is not limited thereto. For example, in some embodiments, the second mask pattern MP2 may have a multi-layer structure including materials having different etching selectivities.

The second mask pattern MP2 may be positioned on both sides of the separation insulating pattern 131. The second mask pattern MP2 may expose a portion of the active layer 202. The active layer 202 exposed by the second mask pattern MP2 may be patterned and removed in a subsequent process.

Specifically, as shown in FIG. 16, in embodiments, the second mask pattern MP2 may include a line portion MP2a extending in a first direction X and a plurality of protrusion portions MP2b extending and protruding from the line portion MP2a in a second direction Y.

The line portion MP2a and the plurality of protrusion portions MP2b of the second mask pattern MP2 are formed together in the same process using the same material, and no boundary may be visible between them.

Depending on the shape of the second mask pattern MP2, the shapes of the active patterns (see ‘AP1 and AP2’ of FIG. 2) formed in the subsequent process may be variously changed.

The line portion MP2a of the second mask pattern MP2 may be positioned to overlap a region of the active layer 202 in which first portions (see ‘AP1a and AP2a’ of FIG. 2) of active patterns (see ‘AP1 and AP2’ of FIG. 2) formed in a subsequent process are defined, and the plurality of protrusion portions MP2b may be positioned to overlap a region of the active layer 202 in which second portions (see ‘AP1b and AP2b’ of FIG. 2) of active patterns (see ‘AP1 and AP2’ of FIG. 2) formed in a subsequent process are defined.

Although not shown in detail in FIG. 16, the line portion MP2a of the second mask pattern MP2 may extend from a region corresponding to the cell array region (see ‘CAR’ of FIG. 1) to a region corresponding to the peripheral circuit region (see ‘PAR’ of FIG. 1).

Accordingly, the first portions (see ‘AP1a and AP2a’ of FIG. 2) of the active patterns (see ‘AP1 and AP2’ of FIG. 2) formed in the process of patterning the active layer 202 using the line portion MP2a of the second mask pattern MP2 as an etching mask may be formed from the cell array region (see ‘CAR’ of FIG. 1) to the peripheral circuit region (see ‘PAR’ of FIG. 1).

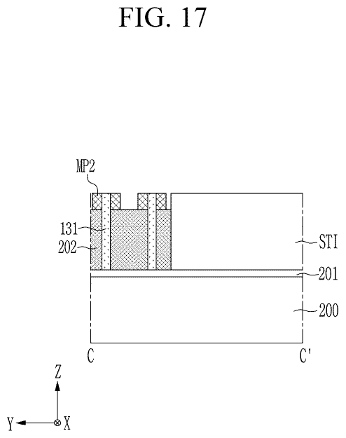

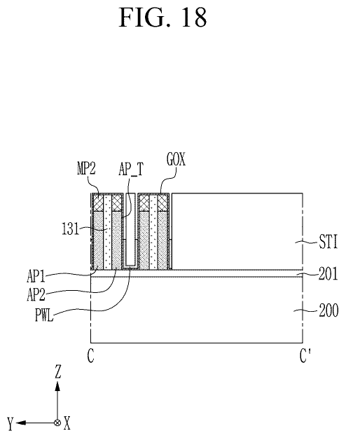

Subsequently, referring further to FIGS. 2 and 18 with FIGS. 16 and 17, the second mask pattern MP2 may be used as an etching mask to pattern the active layer 202 to form a plurality of active patterns AP1 and AP2.

Specifically, the shape and width of the first portions (see ‘AP1a and AP2a’ of FIG. 2) of each of the active patterns AP1 and AP2 may be determined by the shape and width of the line portion MP2a of the second mask pattern MP2, and the shape and width of the second portions (see ‘AP1b and AP2b’ of FIG. 2) of each of the active patterns AP1 and AP2 may be determined by the shape and width of the protrusion portion (MP2b of the second mask pattern MP2.

Accordingly, the planar shape of the first portions (see ‘AP1a and AP2a’ of FIG. 2) of the active patterns AP1 and AP2) may be formed to be substantially equal to the planar shape of the line portion MP2a of the second mask pattern MP2, and the planar shape of the second portions (see ‘AP1b and AP2b’ of FIG. 2) of each of the active patterns AP1 and AP2 may be formed to be substantially equal to the planar shape of the protrusion portion MP2b of the second mask pattern MP2.

The plurality of active patterns AP1 and AP2 formed as the active layer 202 is patterned may define an active pattern trench AP_T. A bottom surface of the active pattern trench AP_T is defined by the buried insulating layer 201, and a side wall of the active pattern trench AP_T may be defined by side surfaces of adjacent active patterns AP1 and AP2 and side surfaces of the second mask pattern MP2.

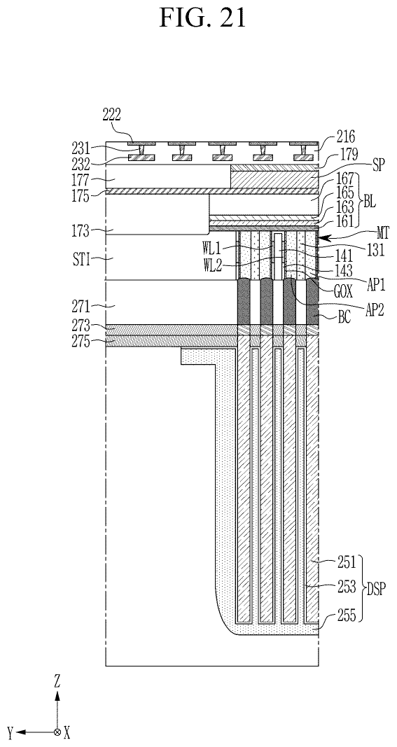

Subsequently, the gate insulating pattern GOX, a preliminary word line PWL for forming word lines (see ‘WL1 and WL2’ of FIG. 21), and the gate separation pattern 141 may be sequentially formed on active patterns AP1 and AP2.

Specifically, the gate insulating pattern GOX may be conformally formed along the bottom surface and sidewalls of the active pattern trench AP_T. The gate insulating pattern GOX may conformally extend along an upper surface of the second mask pattern MP2, an upper surface of the separation insulating pattern 131, a side surfaces of the active patterns AP1 and AP2, and an upper surface of the buried insulating layer 201.

In FIG. 18, the gate insulating pattern GOX is not formed on a side surface and an upper surface of the element isolation layer STI, but is not limited thereto, and in some embodiments, the gate insulating pattern GOX may be conformally formed on the side surface and the upper surface of the element isolation layer STI.

The gate insulating pattern (GOX) may be formed using at least one of an atomic layer deposition (ALD) method, a chemical oxidation (Chemical Oxidation) method, a thermal oxidation (Thermal Oxidation) method, an ultraviolet rays oxidation (UV oxidation) method, a dual plasma oxidation (Dual Plasma Oxidation) method, physical vapor deposition (PVD), thermal chemical vapor deposition (thermal CVD), low-pressure chemical vapor deposition (LP-CVD), and plasma enhanced chemical vapor deposition (PE-CVD) methods. However, the present disclosure is not limited thereto, and the method of forming the gate insulating pattern GOX may be variously changed.

Subsequently, the preliminary word line PWL may be formed on the gate insulating pattern GOX. The preliminary word line PWL may be formed conformally along the surface profile of the gate insulating pattern GOX.

The preliminary word line PWL may contain a conductive material. For example, the preliminary word line PWL may contain at least one of doped polysilicon, conductive metal nitride, conductive metal silicon nitride, metal carbonitride, conductive metal silicide, conductive metal oxide, two-dimensional material, and metal. However, the material cotained in the preliminary word line PWL is not limited thereto, and may be variously changed.

Subsequently, after forming the gate separation pattern 141 in the active pattern trench AP_T, a portion of the preliminary word line PWL may be removed.

Specifically, an insulating material is formed to form the gate separation pattern 141 to entirely cover the preliminary word line PWL formed on the gate insulating pattern GOX and fill the active pattern trench AP_T, and then a portion of the insulating material is removed through a planarization process or the like to form the gate separation pattern 141 in the active pattern trench AP_T.

The insulating material for forming the gate separation pattern 141 may contain silicon oxide, silicon nitride, or a combination thereof, but is not limited thereto.

In a process of removing a portion of an insulating material for forming the gate separation pattern 141, the gate insulating pattern GOX positioned on an upper surface of each of the second mask pattern MP2 and the separation insulation pattern 131 may be exposed. However, it is not limited to thereto.

In some embodiments, in the process of removing the portion of an insulating material for forming the gate separation gate separation pattern 141, the preliminary word line PWL positioned on the upper surface of each of the second mask pattern MP2 and the separation insulating pattern 131 may remain.

Subsequently, an etching process may be performed on the exposed preliminary word line PWL.

In embodiments, the etch process for the preliminary word line PWL may be a dry etch-back process. However, it is not limited thereto, and the etching process method for the preliminary word line PWL may be variously changed.

The etching process for the preliminary word line PWL may be performed until side surfaces of the gate separation pattern 141, which is positioned in the active pattern trench AP_T, and the gate insulating pattern GOX formed on side surfaces of active patterns AP1 and AP2 are exposed.

The etching process for the preliminary word line PWL may be performed until an upper surface of the preliminary word line PWL is positioned at a lower level than an upper surface of the gate separation pattern 141. In this way, in the etching process for the preliminary word line PWL, the level of the upper surface of the preliminary word line PWL may be variously changed.

As a portion of the preliminary word line PWL is removed, the remaining preliminary word line PWL may have an approximately ‘U’ shaped cross-section in the active pattern trench AP_T. That is, the remaining preliminary word line PWL extends along the bottom surface and sidewalls of the active pattern trench AP_T and may cover the bottom surface of the gate separation pattern 141 and portion of the sidewalls adjacent thereto.

The portion of the preliminary word line PWL is removed, and the remaining preliminary word line PWL may be positioned on a side surface of the element isolation layer STI.

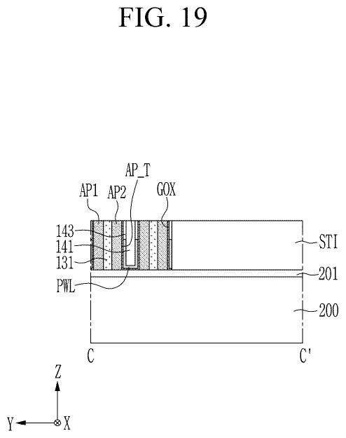

Subsequently, referring further to FIG. 19 with FIG. 18, the first gate capping pattern 143 may be formed on the preliminary word line PWL.

Specifically, after forming an insulating material for forming the first gate capping pattern 143 to fill remaining region in the active pattern trench AP_T where the gate insulating pattern GOX and the preliminary word line PWL are formed, a planarization process may be performed.

The insulating material for forming the first gate capping pattern 143 may contain one of silicon oxide, silicon nitride, or a combination thereof, but is not limited thereto.

In the planarization process, a portion of the second mask pattern MP2, a portion of the gate insulating pattern GOX, a portion of the separation insulating pattern 131, a portion of the first gate capping pattern 143, a portion of the active patterns AP1 and AP2, a portion of the gate separation pattern 141, and a portion of the element isolation layer STI may be removed together.

Accordingly, an upper surfaces of the active patterns AP1 and AP2 are exposed, and an upper surface of the gate insulating pattern GOX, the upper surface of the active patterns AP1 and AP2, an upper surface of the separation insulating pattern 131, an upper surface of the gate separation pattern 141, an upper surface of the first gate capping pattern 143, and an upper surface of the element isolation layer STI may be substantially flat.

The method of manufacturing the semiconductor device according to embodiments may further include a process of forming a mask pattern (not shown in the drawings) that exposes a portion of one surface of each of the active patterns AP1 and AP2, and then doping a dopant into the active patterns AP1 and AP2 exposed by the mask pattern.

Here, the one surface of each of the active patterns AP1 and AP2 may refer to a surface adjacent to the storage contact BC formed in a subsequent process.

Specifically, referring to FIG. 5 with FIG. 19, the mask pattern (not shown in the drawings) may be formed to cover the first portions AP1a and AP2a of each of the active patterns AP1 and AP2 and expose the second portions AP1b and AP2b. Thereafter, the second dopant, which is different from the above-described the first dopant, may be doped into the second portions AP1b and AP2b of each of the active patterns AP1 and AP2 exposed by the mask pattern.

Here, the second dopant may be the n-type dopant such as phosphorus (P), arsenic (As), bismuth (Bi), antimony (SB), or a combination thereof. However, the second dopant is not limited thereto, and may be variously changed.

By doping the second dopant to a predetermined depth in the second portions AP1b and AP2b of each of the active patterns AP1 and AP2, the second dopant regions SDR2_1 and SDR2_2 including the second dopant may be formed in the second portions AP1b and AP2b of each of the active patterns AP1 and AP2.

During the doping process of the second dopant into the second portions AP1b and AP2b of each of the active patterns AP1 and AP2, the first portions AP1a and AP2a may be shielded by the mask pattern, and thus may not be doped with the second dopant.

The doping process for the second portions AP1b and AP2b of each of the active patterns AP1 and AP2 may be performed using the gas phase doping (GPD) process or the plasma doping (PLAD) process, but the doping process method is not limited thereto, and may be variously changed.

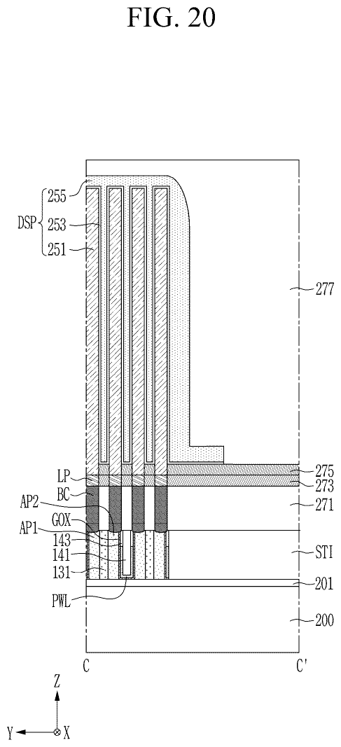

Subsequently, referring to FIG. 20, the contact interlayer insulating layer 271 including a contact hole exposing the active patterns AP1 and AP2 may be formed.

The contact interlayer insulating layer 271 may be formed to expose the upper surfaces of the active patterns AP1 and AP2, and cover the upper surface of the separation insulating pattern 131, the upper surface of the gate insulating pattern GOX, the upper surface of the active patterns AP1 and AP2, the upper surface of the first gate capping pattern 143, and the upper surface of the element isolation layer STI.

Subsequently, inside the contact hole of the contact interlayer insulating layer 271, the plurality of storage contact BC may be formed. The plurality of storage contacts BC may be formed on the first and second active patterns AP1 and AP2.

Subsequently, the pad separation insulating layer 273 which includes a pad hole may be formed on the contact interlayer insulating layer 271, and then, inside the pad hole of the pad separation insulating layer 273, the plurality of landing pads LP may be formed. The plurality of landing pads LP may be formed on the plurality of storage contact BC.

Subsequently, on the pad separation insulating layer 273, the contact etch stop layer 275 may be formed, and then, the first electrode 251 which passes through the contact etch stop layer 275 and be connected to the plurality of landing pads LP, the dielectric film 253 which covers the first electrode 251, and the second electrode 255 which is positioned on the dielectric film 253 may be sequentially formed. The first electrode 251, the dielectric film 253, and the second electrode 255 may constitute a cell capacitor DSP.

Subsequently, the third cell insulating layer 277 which entirely covers the cell capacitor DSP may be formed.

In some embodiments, an additional doping process may be performed to dope dopants into the first portions (see ‘AP1a and AP2a’ of FIG. 5) of each of the active patterns AP1 and AP2, either before performing the above-described doping process for the second portions (see ‘AP1b and AP2b’ of FIG. 5) of the active patterns AP1 and AP2, or before forming the above-described storage contacts BC on the active patterns AP1 and AP2.

Specifically, referring to FIG. 5 with FIG. 19, a mask pattern (not shown in the drawings) may be formed to expose the first portions AP1a and AP2a and cover the second portions AP1b and AP2b of each of the active patterns AP1 and AP2. Thereafter, the above-described first dopant may be additionally doped into the first portions AP1a and AP2a of the active patterns AP1 and AP2 exposed by the mask pattern. Here, the first dopant may be the p-type dopant.

As such, by additionally doping the above-described first dopant into the first portions AP1a and AP2a of each of the active patterns AP1 and AP2, the concentration of the first dopant included in each of the first portions AP1a and AP2a may be higher than the concentration of the first dopant included in each of the second portions AP1b and AP2b.

Accordingly, as described above, by controlling the concentration of the dopant included in each of the first portions AP1a and AP2a and the second portions AP1b and AP2b of the active patterns AP1 and AP2, the channel of the memory transistor MT may be formed only in a specific region.

Further, in some embodiments, the second active capping pattern (see ‘135’ of FIG. 8) may be formed between the active patterns AP1 and AP2 and the storage contact BC by partially removing the active patterns AP1 and AP2 before the storage contact BC are formed.

Specifically, referring to FIG. 8 with FIG. 19, a mask pattern (not shown in the drawings) may be formed to expose the first portions AP1a and AP2a and cover the second portions AP1b and AP2b of each of the active patterns AP1 and AP2. Thereafter, a portion of each of the exposed first portions AP1a and AP2a of the active patterns AP1 and AP2 may be removed.

Accordingly, each of the first portions AP1a and AP2a of the active patterns AP1 and AP2 may be recessed to a predetermined depth.

Subsequently, the second active capping pattern 135 may be formed in the recessed regions where a portion of each of the first portions AP1a and AP2a of the active patterns AP1 and AP2 has been removed.

The process of forming the second active capping pattern 135 may include filling an insulating material in regions where portions of the first portions AP1a and AP2a of the active patterns AP1 and AP2 have been removed, and performing a planarization process.

The insulating material for forming the second active capping pattern 135 may contain, for example, silicon oxide, silicon nitride, silicon oxynitride, and/or a low-k material, but is not limited thereto.

Subsequently, referring to FIG. 21 with FIG. 20, a back surface lapping process of removing the sub substrate 200 may be performed. Removing the sub substrate 200 may include sequentially performing a grinding process and an etching process to expose the buried insulating layer 201.

Subsequently, the buried insulating layer 201 may be removed. As the buried insulating layer 201 is removed, the active patterns AP1 and AP2, the gate insulating pattern GOX, and the separation insulating pattern 131 may be exposed.

Subsequently, the exposed gate insulating pattern GOX may be removed to expose the preliminary word line PWL.

Subsequently, a pair of first and second word lines WL1 and WL2 may be formed on both sides of the gate separation pattern 141 by performing an etch back process or a patterning process for removing a portion of the preliminary word line PWL, and then, the gate capping pattern 147 may be formed so as to cover the word lines WL1 and WL2 and the second gate capping pattern 145.

The process of forming the second gate capping pattern 145 may include forming an insulating material to fill a region which the preliminary word line PWL has been removed, and performing a planarization process.

Accordingly, the active patterns AP1 and AP2, the separation insulating pattern 131, the gate insulating pattern GOX, and the second gate capping pattern 145 may be substantially planarized.

The insulating material for forming second gate capping pattern 145 may contain silicon oxide, silicon nitride, or a combination thereof, but is not limited thereto.

Subsequently, on the active patterns AP1 and AP2, the polysilicon layer 161, the first metal layer 163, the second metal layer 165, and the bit line capping layer 167 may be sequentially formed. The polysilicon layer 161, the first metal layer 163, the second metal layer 165, and the bit line capping layer 167 may constitute a bit line BL.

The method of manufacturing the semiconductor device according to embodiments may further include, before forming the bit line BL, forming a mask pattern (not shown in the drawings) to expose a portion of the other surface of each of the active patterns AP1 and AP2, and performing a doping process to dope dopants into the active patterns AP1 and AP2 exposed by the mask pattern.

Here, the other surface of each of the active patterns AP1 and AP2 may refer to a surface adjacent to a bit line BL formed in a subsequent process.

Specifically, referring to FIG. 5 with FIG. 19, a mask pattern (not shown in the drawings) may be formed to cover the first portions AP1a and AP2a and expose the second portions AP1b and AP2b of each of the active patterns AP1 and AP2. Thereafter, the second dopant different from the above-described first dopant may be doped into the exposed second portions AP1b and AP2b of the active patterns AP1 and AP2 By doping the second dopant into the second portions AP1b and AP2b of each of the active patterns AP1 and AP2 to a predetermined depth, first dopant regions SDR1_1 and SDR1_2 including the second dopant may be formed in the second portions AP1b and AP2b of each of the active patterns AP1 and AP2.

The process of forming the first dopant regions SDR1_1 and SDR1_2 may be performed in substantially the same manner as the process of forming the second dopant regions SDR2_1 and SDR2_2.

Further, the second dopant doped in the first dopant regions SDR1_1 and SDR1_2 may be substantially the same as the second dopant doped in the second dopant regions SDR2_1 and SDR2_2. However, the present disclosure is not limited thereto, and the process of forming the first dopant regions SDR1_1 and SDR1_2 may be performed in a manner different from the process of forming the second dopant regions SDR2_1 and SDR2_2, or the second dopant doped into the first dopant regions may be different from the second dopant doped into the second dopant regions.

During the doping process of the second dopant into the second portions AP1b and AP2b of each of the active patterns AP1 and AP2, the first portions AP1a and AP2a may be shielded by the mask pattern, and thus may not be doped with the second dopant.

Further, in some embodiments, the first active capping pattern (see ‘133’ of FIG. 8) may be formed between the active patterns AP1 and AP2 and the bit line BL by partially removing the active patterns AP1 and AP2 before the bit line BL are formed.

Specifically, referring to FIG. 8 with FIG. 21, a mask pattern (not shown in the drawings) may be formed to expose the first portions AP1a and AP2a and cover the second portions AP1b and AP2b of each of the active patterns AP1 and AP2. Thereafter, a portion of each of the exposed first portions AP1a and AP2a of the active patterns AP1 and AP2 may be removed.

Accordingly, each of the first portions AP1a and AP2a of the active patterns AP1 and AP2 may be recessed to a predetermined depth.

Subsequently, the first active capping pattern 135 may be formed in the recessed regions where a portion of each of the first portions AP1a and AP2a of the active patterns AP1 and AP2 has been removed.

The process of forming the first active capping pattern 133 may be performed in substantially the same manner as the process of forming the second active capping pattern 135.

Further, the first active capping pattern 133 may contain the same material as the second active capping pattern 135. However, the present disclosure is not limited thereto, and the process of forming the first active capping pattern 133 may be performed in a manner different from the process of forming the second active capping pattern 135, or the first active capping pattern 133 may contain a material different from that of the second active capping pattern 135.

Subsequently, the second cell insulating layer 173 may be formed on the element isolation layer STI, and then, on the bit line BL and the second cell insulating layer 173, the spacer insulating layer 175, the first cell insulating layer 177, the shield pattern SP, and the shield capping layer 179 may be sequentially formed. However, the order in which the bit line BL, the second cell insulating layer 173, the spacer insulating layer 175, the first cell insulating layer 177, the shield pattern SP, and the shield capping layer 179 are formed is not limited thereto, and may be variously changed.

Subsequently, the second bonding insulating layer 216 may be formed on the first cell insulating layer 177 and the shielding capping layer 179.

Subsequently, the cell connection wiring 232, the cell connection wiring via 231, and the second bonding pad 222 may be formed in the second bonding insulating layer 216.

In FIG. 21, it is shown that the second bonding insulating layer 216 is a single layer, however, the second bonding insulating layer 216 may have a structure in which a plurality of layers is stacked, and the plurality of layers may be formed by separate processes.

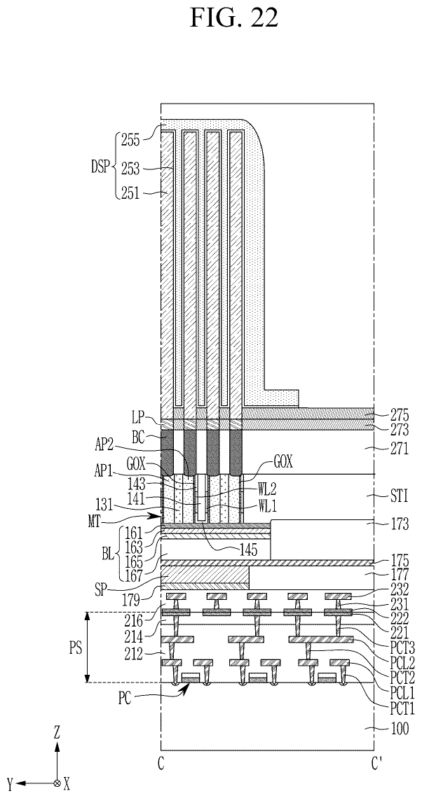

Subsequently, referring to FIG. 4 together with FIG. 22, on the substrate 100, the peripheral circuit structure PS which includes the peripheral circuit PC, the peripheral circuit contacts PCT1, PCT2, and PCT3, the peripheral circuit wiring lines PCL1 and PCL2, the peripheral circuit insulating layer 212, the first bonding insulating layer 214, and the first bonding pad 221 may be formed.

Subsequently, the first bonding pad 221 and the second bonding pad 222 may be bonded to each other, and the first bonding insulating layer 214 and the second bonding insulating layer 216 may be bonded together.

Accordingly, the first bonding pad 221 and the second bonding pad 222 may be in contact with each other to form a metal bond, and the first bonding insulating layer 214 and the second bonding insulating layer 216 may be in contact with each other to form a junction insulating layer.

Subsequently, inside the third cell insulating layer 277, the first cell wiring contact 261 and the first cell wiring line 262 may be formed. Subsequently, on the third cell insulating layer 277, the fourth cell insulating layer 279, the second cell wiring contact 263 and the second cell wiring line 264 may be formed.

While this disclosure has been described in connection with what is presently considered to be practical embodiments, it is to be understood that the invention is not limited to the disclosed embodiments. On the contrary, it is intended to cover various modifications and equivalent arrangements included within the spirit and scope of the appended claims.

What is claimed is:

1. A semiconductor device comprising:
a substrate,
a bit line positioned on the substrate and extending in a first direction,
a word line positioned on the bit line and extending in a second direction intersecting the first direction,
an active pattern extending in a third direction substantially perpendicular to the first direction and the second direction, and
a cell capacitor positioned on the active pattern,
wherein the active pattern includes the following:
a first portion extending in the second direction, and
a plurality of second portions protruding from the first portion in a first direction and positioned between the first portion and the word line.

2. The semiconductor device of claim 1, wherein:
a width of the first portion in the first direction is different from a width of the second portion in the first direction.

3. The semiconductor device of claim 1, wherein:
a length of the first portion in the third direction is different from a length of the second portion in the third direction.

4. The semiconductor device of claim 1, further comprising:
a storage contact positioned between the active pattern and the cell capacitor,
wherein the first portion of the active pattern is spaced apart from at least one of the bit line and the storage contact.

5. A semiconductor device comprising:
a substrate,
a bit line positioned on the substrate and extending in a first direction,
a word line positioned on the bit line and extending in a second direction intersecting the first direction,
an active pattern extending in a third direction substantially perpendicular to the first direction and the second direction,
a cell capacitor positioned on the active pattern, and
a storage contact positioned between the active pattern and the cell capacitor,
wherein the active pattern includes the following:
a first portion extending in the second direction, and
a plurality of second portions protruding from the first portion in a first direction and positioned between the first portion and the word line,
wherein each of the plurality of second portions includes:
a first dopant region connected to the bit line,
a second dopant region connected to the storage contact, and
a channel region positioned between the first dopant region and the second dopant region.

6. The semiconductor device of claim 5, wherein:
a length of the first portion in the third direction is shorter than the length of the second portion in the third direction.

7. The semiconductor device of claim 6, wherein:
the first portion includes a first surface adjacent to the bit line and a second surface adjacent to the storage contact,
the first surface of the first portion is spaced apart from the bit line.

8. The semiconductor device of claim 7, wherein:
the second surface of the first portion is spaced apart from the storage contact.

9. The semiconductor device of claim 5, wherein:
the storage contact does not overlap the first portion in the third direction and overlaps the second portion in the third direction.

10. The semiconductor device of claim 9, wherein:
the first portion includes a first surface adjacent to the bit line and a second surface adjacent to the storage contact,
the first surface of the first portion is spaced apart from the bit line.

11. The semiconductor device of claim 5, wherein:
a width of the first portion in the first direction is greater than a width of the second portion in the first direction.

12. The semiconductor device of claim 5, wherein:
the first dopant region and the second dopant region of the second portion include a first dopant,
the first portion and the channel region of the second portion include a second dopant that is different from the first dopant, and
a concentration of the second dopant in the first portion is different from a concentration of the second dopant in the channel region.

13. A semiconductor device comprising:
a substrate including a cell array region and a peripheral circuit region adjacent to the cell array region,
a bit line positioned on the substrate and extending in a first direction,
a first word line and a second word line positioned on the bit line and extending in a second direction intersecting the first direction,
a plurality of active patterns positioned between the first word line and the second word line and extending in a third direction substantially perpendicular to the first direction and the second direction,
a plurality of cell capacitors positioned on the plurality of active patterns, and
a plurality of storage contacts respectively positioned between the plurality of active patterns and the plurality of cell capacitors,
wherein each of the plurality of active patterns includes:
a first portion extending in the second direction from the cell array region to the peripheral circuit region, and
a plurality of second portions protruding from the first portion toward one side or the other side in the first direction, and positioned between the first portion and either the first word line or the second word line,
wherein each of the plurality of second portions includes:
a first dopant region connected to the bit line,
a second dopant region connected to each of the storage contacts, and
a channel region positioned between the first dopant region and the second dopant region.

14. The semiconductor device of claim 13, further comprising:
a back gate electrode positioned between the first portions of each of the plurality of active patterns and extending in the second direction.

15. The semiconductor device of claim 14, wherein:
a width of the first portion in the first direction is smaller than a width of the second portion in the first direction.

16. The semiconductor device of claim 13, further comprising:
a separation insulating pattern positioned between the first portions of each of the plurality of active patterns and extending in the second direction.

17. The semiconductor device of claim 13, wherein:
the first portion includes a first surface adjacent to the bit line and a second surface adjacent to the storage contacts,
the semiconductor device further includes a first active capping pattern positioned between the second surface of the first portion and the storage contacts.

18. The semiconductor device of claim 17, further comprising:
a second active capping pattern positioned between the first surface of the first portion and the bit line.

19. The semiconductor device of claim 18, wherein:
a length of the first active capping pattern in the third direction is greater than or substantially equal to a length of the second dopant region in the third direction, and
a length of the second active capping pattern in the third direction is greater than or substantially equal to a length of the first dopant region in the third direction.

20. The semiconductor device of claim 13, further comprising:
an active pattern contact positioned in the peripheral circuit region and configured to apply a body voltage to the first portion.
